(19) United States
(12) Patent Application Publication
(10) Pub. No.: US 2023/0197752 A2
(43) Pub. Date: Jun. 22, 2023

(54) IMAGE SENSOR AND ELECTRONIC DEVICE

(71) Applicant: SONY SEMICONDUCTOR SOLUTIONS CORPORATION, Kanagawa (JP)

(72) Inventors: Nobuyuki KUBOI, Kanagawa (JP); Koji NAGAHIRO, Kanagawa (JP)

(73) Assignee: SONY SEMICONDUCTOR SOLUTIONS CORPORATION, Kanagawa (JP)

(21) Appl. No.: 17/055,690

(22) PCT Filed: May 23, 2019
(86) PCT No.: PCT/JP2019/020381

§ 371 Date: Nov. 16, 2020

(30) Foreign Application Priority Data
Jun. 6, 2018 (JP) 2018-108605

(51) Int. Cl. H01L 27/146

(52) U.S. Cl. CPC H01L 27/1463; H01L 27/14645; H01L 27/14614; H01L 27/14625; H01L 27/14621; H01L 27/14623; H01L 27/14627; H01L 27/14689

(57) ABSTRACT

The image sensor includes: a substrate; a first pixel including a first photoelectric conversion region that is provided in the substrate; a second pixel including a second photoelectric conversion region that is provided in the substrate so as to be adjacent to the first photoelectric conversion region; a first separation portion provided between the first photoelectric conversion region and the second photoelectric conversion region in the substrate; and a second separation portion that separates a pixel group including at least the first pixel and the second pixel from a pixel group adjacent thereto, in which there is at least one protruding portion of the first separation portion in at least one photoelectric conversion region of the first photoelectric conversion region and the second photoelectric conversion region, and a p-type impurity region and an n-type impurity region are stacked on a side surface of the protruding portion. The present technique can be applied to, for example, an image sensor.

### TECHNICAL FIELD

The present technique relates to an image sensor and an electronic device, for example, an image sensor and an electronic device in which a charge storage capacity of a photodiode is increased.

### BACKGROUND ART

As an imaging device in digital video cameras, digital still cameras, mobile phones, smartphones, wearable devices, or the like, there is a complementary metal oxide semiconductor (CMOS) image sensor which reads out photogenerated charges accumulated in a pn junction capacitance of a photodiode (PD), which is a photoelectric conversion element, through a MOS transistor.

In recent years, in a CMOS image sensor, miniaturization of a PD itself has been required along with miniaturization of devices. However, if a light receiving area of a PD is simply reduced, light receiving sensitivity thereof is lowered, and it becomes difficult to realize high definition image quality. For this reason, in a CMOS image sensor, it is required to improve light receiving sensitivity while miniaturizing a PD.

As a technique for improving light receiving sensitivity of a CMOS image sensor using a silicon substrate, PTL 1 and PTL 2 propose methods of forming a plurality of pn junction regions in a comb shape in a depth direction of a PD by implanting impurities (ion implantation). PTL 3 proposes a method of forming a plurality of pn junction regions in a PD in a lateral direction thereof by implanting impurities.

### CITATION LIST

### Patent Literature

[PTL 1]
JP 2008-16542A

[PTL 2]
JP 2008-300826A

[PTL 3]
JP 2016-111082A

### SUMMARY

### Technical Problem

According to PTL 1 to PTL 3, since the pn junction regions are formed in the PD using impurity implantation, It is difficult to form a uniform p-type region or n-type region at a desired concentration, it is difficult to form a steep pn junction, and thus sufficient sensitivity improvement is not easily achieved. Further, high energy implantation is required to form a pn junction region at a deep position in the PD by implanting impurities. For this reason, it is difficult to form a pn junction region at a deep position in the PD by implanting impurities.

In a case in which a pn junction region is formed in a PD in a comb shape as in PTL 1 to PTL 3, it is difficult to form the pn junction region at a deep portion in the PD and it is difficult to form p-type regions and n-type regions of a plurality of pn junction regions at a uniform concentration. Therefore, according to PTL 1 to PTL 3, it is difficult to improve the sensitivity.

Further, when the impurities are implanted, the substrate may be damaged and defects may be formed. If such defects are formed, white spots or white scratches in a PD may be aggravated.

It is desired to form a steep pn junction and improve sensitivity of a PD while inhibiting damage to a substrate in the process of forming pn junction regions.

The present technique has been made in view of such circumstances and is configured to be able to improve sensitivity of a PD.

### Solution to Problem

An image sensor according to one aspect of the present technique includes: a substrate; a first pixel including a first photoelectric conversion region that is provided in the substrate; a second pixel including a second photoelectric conversion region that is provided in the substrate so as to be adjacent to the first photoelectric conversion region; a first separation portion provided in the substrate so as to be between the first photoelectric conversion region and the second photoelectric conversion region; and a second separation portion that separates a pixel group including at least the first pixel and the second pixel from a pixel group adjacent thereto, in which there is at least one protruding portion of the first separation portion in at least one photoelectric conversion region of the first photoelectric conversion region and the second photoelectric conversion region, and a p-type impurity region and an n-type impurity region are stacked on a side surface of the protruding portion.

An electronic device according to an aspect of the present technique includes an image sensor including: a substrate; a first pixel including a first photoelectric conversion region that is provided in the substrate; a second pixel including a second photoelectric conversion region that is provided in the substrate so as to be adjacent to the first photoelectric conversion region; a first separation portion provided in the substrate so as to be between the first photoelectric conversion region and the second photoelectric conversion region; and a second separation portion that separates a pixel group including at least the first pixel and the second pixel from a pixel group adjacent thereto, in which there is at least one protruding portion of the first separation portion in at least one photoelectric conversion region of the first photoelectric conversion region and the second photoelectric conversion region, and a p-type impurity region and an n-type impurity region are stacked on a side surface of the protruding portion.

The image sensor according to one aspect of the present technique includes the substrate, the first pixel including the first photoelectric conversion region that is provided in the substrate, the second pixel including the second photoelectric conversion region that is provided in the substrate so as to be adjacent to the first photoelectric conversion region, the first separation portion provided in the substrate so as to be between the first photoelectric conversion region and the second photoelectric conversion region, and the second separation portion that separates the pixel group including at least the first pixel and the second pixel from the pixel group adjacent thereto. In addition, there is at least one protruding portion of the first separation portion in at least one photoelectric conversion region of the first photoelectric conversion region and the second photoelectric conversion region, and the p-type impurity region and the n-type impurity region are stacked on the side surface of the protruding portion.

The electronic device according to one aspect of the present technique is configured to include the image sensor.

### Advantageous Effects of Invention

According to one aspect of the present technique, it is possible to improve sensitivity of a PD.

Also, the effects described herein are not necessarily limited and may be any effect described in the present disclosure.

### BRIEF DESCRIPTION OF DRAWINGS

FIG. 1 is a diagram showing a configuration example of an imaging device.

FIG. 2 is a diagram showing a configuration example of an image sensor.

FIG. 3 is a circuit diagram of a pixel.

FIG. 4 is a plan view of a front surface side showing a first configuration example of a pixel to which the present technique is applied.

FIG. 5 is a vertical cross-sectional view showing the first configuration example of the pixel to which the present technique is applied.

FIG. 6 is a vertical cross-sectional view of a first embodiment of the pixel to which the present technique is applied.

FIG. 7 is a diagram for explaining a protruding portion.

FIG. 8 is a diagram for explaining an increase in a charge storage capacity.

FIG. 9 is a diagram for explaining formation of the protruding portion.

FIG. 10 is a diagram for explaining formation of the protruding portion.

FIG. 11 is a vertical cross-sectional view showing a second configuration example of the pixel to which the present technique is applied.

FIG. 12 is a vertical cross-sectional view showing a third configuration example of the pixel to which the present technique is applied.

FIG. 13 is a vertical cross-sectional view showing a fourth configuration example of the pixel to which the present technique is applied.

FIG. 14 is a vertical cross-sectional view showing a fifth configuration example of the pixel to which the present technique is applied.

FIG. 15 is a vertical cross-sectional view showing a sixth configuration example of the pixel to which the present technique is applied.

FIG. 16 is a vertical cross-sectional view showing a seventh configuration example of the pixel to which the present technique is applied.

FIG. 17 is a vertical cross-sectional view showing an eighth configuration example of the pixel to which the present technique is applied.

FIG. 18 is a vertical cross-sectional view showing a ninth configuration example of the pixel to which the present technique is applied.

FIG. 19 is a vertical cross-sectional view showing a tenth configuration example of the pixel to which the present technique is applied.

FIG. 20 is a vertical cross-sectional view showing an eleventh configuration example of the pixel to which the present technique is applied.

FIG. 21 is a vertical cross-sectional view showing a twelfth configuration example of the pixel to which the present technique is applied.

FIG. 22 is a vertical cross-sectional view showing a thirteenth configuration example of the pixel to which the present technique is applied.

FIG. 23 is a vertical cross-sectional view showing a fourteenth configuration example of the pixel to which the present technique is applied.

FIG. 24 is a diagram showing an example of a schematic configuration of an endoscopic surgery system.

FIG. 25 is a block diagram showing an example of a functional configuration of a camera head and a CCU.

FIG. 26 is a block diagram showing an example of a schematic configuration of a vehicle control system.

FIG. 27 is an explanatory diagram showing an example of installation positions of a vehicle outside information detection unit and an imaging unit.

### DESCRIPTION OF EMBODIMENTS

Modes for embodying the present technique (hereinafter referred to as “embodiments”) will be described below.

Since the present technique can be applied to an imaging device, a case in which the present technique is applied to an imaging device will be described as an example. In addition, although the imaging device will be described below as an example herein, the present technique is not limited to an application to the imaging device and can be applied to all electronic devices that use the imaging device as an image capturing unit (photoelectric conversion unit), for example, imaging devices such as digital still cameras and video cameras, mobile terminal devices having an imaging function such as mobile phones, and copiers that use an imaging device as an image reading unit. Also, there is also a mode of a module type being mounted in an electronic device, that is, a case in which a camera module is used as an imaging device.

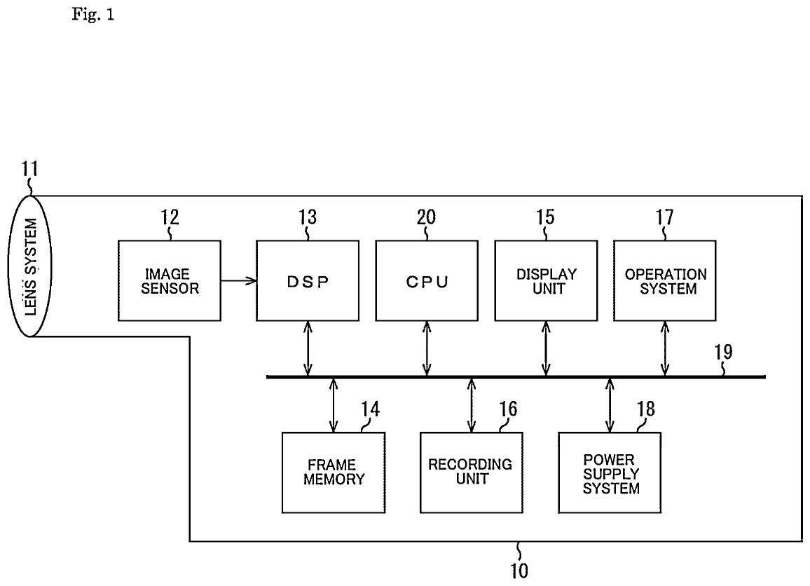

FIG. 1 is a block diagram showing a configuration example of an imaging device which is an example of an electronic device of the present disclosure. As shown in FIG. 1, the imaging device 10 has an optical system including a lens group 11 and the like, an image sensor 12, a DSP circuit 13 that is a camera signal processing unit, a frame memory 14, a display unit 15, a recording unit 16, an operation system 17, a power supply system 18, and the like.

In addition, the DSP circuit 13, the frame memory 14, the display unit 15, the recording unit 16, the operation system 17, and the power supply system 18 are connected to each other via a bus line 19. The CPU 20 controls each unit in the imaging device 10.

The lens group 11 captures incident light (image light) from a subject and forms an image on an imaging surface of the image sensor 12. The image sensor 12 converts a light amount of the incident light imaged on the imaging surface by the lens group 11 into an electric signal for each pixel and outputs the electric signal as a pixel signal. As the image sensor 12, an image sensor including pixels described below can be used.

The display unit 15 includes a panel-type display unit such as a liquid crystal display unit or an organic electro luminescence (EL) display unit and displays a video or a still image captured by the image sensor 12. The recording unit 16 records a video or a still image captured by the image sensor 12 on a recording medium such as a video tape or a digital versatile disk (DVD).

The operation system 17 issues operation commands for various functions of the present imaging device on the basis of operations of a user. The power supply system 18 appropriately supplies various power supplies serving as operation power supplies for the DSP circuit 13, the frame memory 14, the display unit 15, the recording unit 16, and the operation system 17 to these supply targets.

<Configuration of Image Sensor>

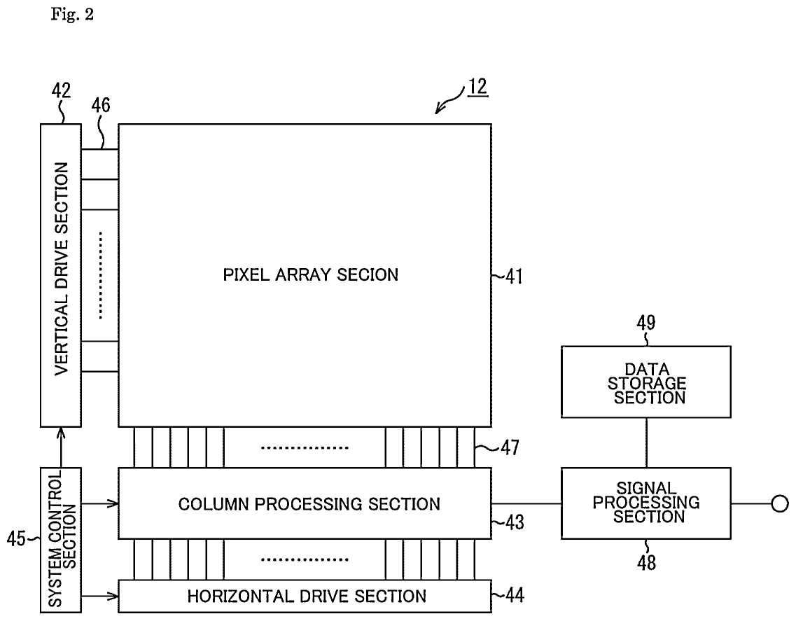

FIG. 2 is a block diagram showing a configuration example of the image sensor 12. The image sensor 12 can be a complementary metal oxide semiconductor (CMOS) image sensor.

The image sensor 12 is configured to include a pixel array section 41, a vertical drive section 42, a column processing section 43, a horizontal drive section 44, and a system control section 45. The pixel array section 41, the vertical drive section 42, the column processing section 43, the horizontal drive section 44, and the system control section 45 are formed on a semiconductor substrate (chip) (not shown).

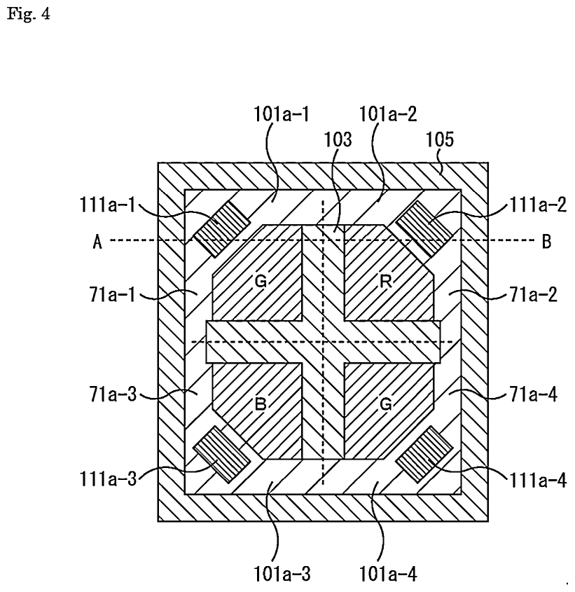

In the pixel array section 41, unit pixels (for example, pixels 101 in FIG. 4) each having a photoelectric conversion element that generates a photogenerated charge of an amount of charge corresponding to an amount of incident light and accumulates the charge therein are disposed two-dimensionally in a matrix. Also, in the following, a photogenerated charge having an amount of charge corresponding to the amount of incident light may be simply referred to as a “charge”, and the unit pixel may be simply referred to as a “pixel”.

Further, in the pixel array section 41, for the matrix of pixel arrays, pixel drive lines 46 are formed for each row in a lateral direction of the figure (in an arrangement direction of pixels in a pixel row), and vertical signal lines 47 are formed for each column in a longitudinal direction of the figure (in an arrangement direction of pixels in a pixel column). One end of each pixel drive line 46 is connected to an output end corresponding to each row of the vertical drive section 42.

The image sensor 12 further includes a signal processing section 48 and a data storage section 49. The signal processing section 48 and the data storage section 49 may be realized by an external signal processing unit provided on a substrate separately from the image sensor 12, for example, via a process using a digital signal processor (DSP) or software, and may be mounted on the same substrate along with the image sensor 12.

The vertical drive section 42 is a pixel drive section that includes a shift register, an address decoder, and the like, and drives each pixel of the pixel array section 41 simultaneously for all pixels or for each row. Although not specifically shown in the figure, the vertical drive section 42 is configured to have a read scanning system, a sweep scanning system, or a batch sweep and batch transfer.

The read scanning system sequentially selects and scans the unit pixels in the pixel array section 41 for each row in order to read out signals from the unit pixels. In the case of row drive (a rolling shutter operation), for sweeping, sweep scanning is performed prior to read scanning by a shutter speed time for the read row in which the read scanning is performed by the read scanning system. Further, in the case of global exposure (a global shutter operation), batch sweep is performed prior to batch transfer by a shutter speed time.

Due to this sweeping, unnecessary charges are swept (reset) from the photoelectric conversion element of the unit pixels in the read row. Then, a so-called electronic shutter operation is performed by sweeping (resetting) the unnecessary charges. Here, the electronic shutter operation is an operation of discarding photogenerated charges of the photoelectric conversion element and newly starting exposure (starting accumulation of the photogenerated charges).

The signal read by a read operation using the read scanning system corresponds to an amount of light incident after a latest read operation or an electronic shutter operation. In the case of row drive, a period from a read timing of the latest read operation or a sweep timing of the electronic shutter operation to a read timing of a current read operation becomes a photogenerated charge accumulation period (exposure period) in the unit pixel. In the case of global exposure, a period from batch sweep to batch transfer becomes the accumulation period (exposure period).

A pixel signal output from each unit pixel in the pixel row selectively scanned by the vertical drive section 42 is supplied to the column processing section 43 through each of the vertical signal lines 47. The column processing section 43 performs, for each pixel column of the pixel array section 41, predetermined signal processing on the pixel signal output from each unit pixel in a selected row through the vertical signal line 47 and temporarily holds the pixel signal after the signal processing.

Specifically, the column processing section 43 performs, as the signal processing, at least noise removal processing such as correlated double sampling (CDS) processing. Due to the correlated double sampling performed by the column processing section 43, pixel-specific fixed pattern noises such as reset noises and a variation in threshold of an amplification transistor are removed. Further, in addition to the noise removal processing, the column processing section 43 may also be provided with, for example, an analog-digital (AD) conversion function so that a signal level can be output as a digital signal.

The horizontal drive section 44 includes a shift register, an address decoder, and the like and sequentially selects unit circuits corresponding to the pixel columns of the column processing section 43. By this selective scanning performed by the horizontal drive section 44, pixel signals processed by the column processing section 43 are sequentially output to the signal processing section 48.

The system control section 45 includes a timing generator for generating various timing signals, and the like and performs drive control of the vertical drive section 42, the column processing section 43, the horizontal drive section 44, and the like on the basis of various timing signals generated by the timing generator.

The signal processing section 48 has at least an addition processing function and performs a variety of signal processing such as addition processing on the pixel signals output from the column processing section 43. The data storage section 49 temporarily stores data necessary for the signal processing in the signal processing section 48.

<Circuit of Image Sensor>

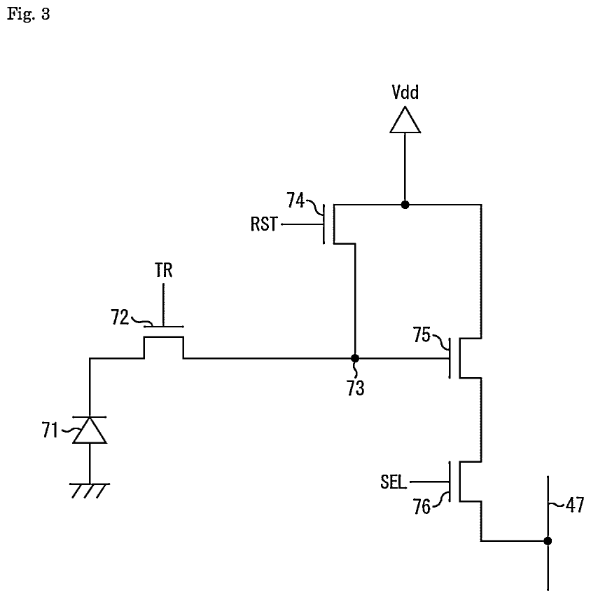

FIG. 3 is a circuit diagram of the image sensor 12. In the image sensor 12, a plurality of transistors are formed in a wiring layer, which will be described later, and connectional relationships of these transistors will be described.

A transfer transistor 72, a floating diffusion (FD) 73, a reset transistor 74, an amplification transistor 75, and a selection transistor 76 are formed in the image sensor 12.

A photodiode (PD) 71 generates and accumulates charges (signal charges) corresponding to an amount of received light. The PD 71 has an anode terminal grounded and a cathode terminal connected to the FD 73 via the transfer transistor 72.

When turned on by a transfer signal TR, the transfer transistor 72 reads a charge generated in the PD 71 and transfers the charge to the FD 73.

The FD 73 holds the charge read from the PD 71. When turned on by a reset signal RST, the reset transistor 74 resets a potential of the FD 73 by discharging the charge accumulated in the FD 73 to a drain (a constant voltage source Vdd).

The amplification transistor 75 outputs a pixel signal corresponding to the potential of the FD 73. That is, the amplification transistor 75 constitutes a source follower circuit with a load MOS (not shown) as a constant current source connected via the vertical signal line 47, and a pixel signal indicating a level corresponding to the charge accumulated in the FD 73 is output from the amplification transistor 75 to the column processing section 43 (FIG. 2) via the selection transistor 76 and the vertical signal line 47.

The selection transistor 76 is turned on when a pixel 31 is selected by a selection signal SEL and outputs a pixel signal of the pixel 31 to the column processing section 43 via the vertical signal line 47. Each signal line through which the transfer signal TR, the selection signal SEL, and the reset signal RST are transmitted corresponds to the pixel drive line 46 in FIG. 2.

The pixel can be configured as described above, but the configuration is not limited thereto, and other configurations can be adopted.

<Configuration of Pixel in First Embodiment>

FIG. 4 is a diagram showing an arrangement example of the unit pixel 101 disposed in a matrix in the pixel array section 41. The pixel 101 in a first embodiment will be described as a pixel 101a.

In the pixel array section 41, a plurality of the unit pixels 101a are disposed in a matrix. FIG. 4 illustrates four 2×2 pixels 101a disposed in the pixel array section 41.

Although a case in which the present technique is applied to an image sensor in which four pixels for outputting red (R), green (G), and blue (B) color lights are arranged will be described below as an example in the following description, the present technique can be applied to other color arrangements. For example, it can be applied to a case in which white (W) pixels that output white are disposed. When the color arrangement includes W pixels, the W pixel functions as a pixel having spectral sensitivity that is a panchromatic property, and the R pixel, the G pixel, and the B pixel function as pixels having spectral sensitivities each of which has a characteristic in its respective color.

Further, the present technique can also be applied to a case in which the color arrangement is a complementary color system such as yellow (Y), cyan (C), and magenta (M). That is, although what degree the spectral sensitivity is not a limitation when the present technique is applied, here, as an example, the case in which the color arrangement has red (R), green (G), and blue (B) will be described as an example.

The four pixels that output red (R), green (G), and blue (B) light are disposed in a matrix in a display region, as shown in FIG. 4, for example. In FIG. 4, each rectangle schematically represents the pixel 101a. In addition, a symbol indicating a type of color filter (colored light output from each pixel) is shown inside each rectangle. For example, “G” is attached to the G pixel, “R” is attached to the R pixel, and “B” is attached to the B pixel. The same applies to the following description.

The four 2×2 pixels 101a shown in FIG. 4 are described as one pixel group. One pixel group includes four 2×2 pixels 101a, and in the example shown in FIG. 4, a pixel 101a-1 that is a G pixel is disposed at the upper left, and a pixel 101a-2 that is an R pixel is disposed at the upper right, a pixel 101a-3 that is a B pixel is disposed at the lower left, and a pixel 101a-4 that is a G pixel is disposed at the lower right.

Although not shown here, the present technique can also be applied to a case in which the four pixels included in the one pixel group share the reset transistor 74, the amplification transistor 75, and the selection transistor 76, and the pixels share the FD 73 (all shown in FIG. 3).

Further, in a case in which it is unnecessary to distinguish the pixels 101a-1 to 101a-4 individually, the pixels will be simply described as the pixel 101a. Other parts will be described in the same manner.

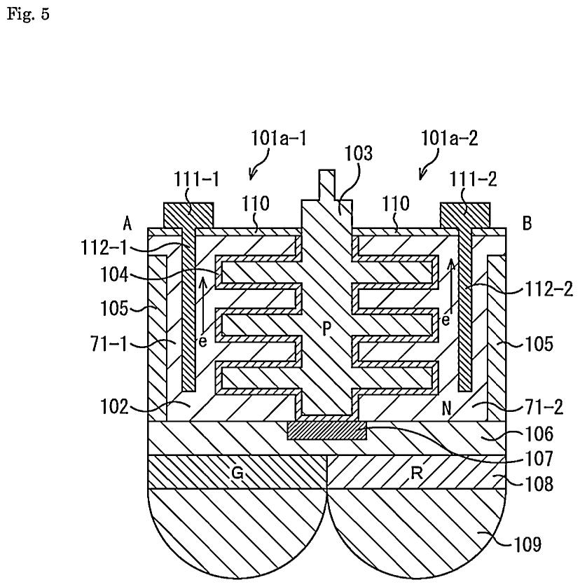

In FIG. 4, one square represents one pixel 101a. The pixel 101a is configured to include the photodiode (PD) 71. A pixel group separation region 105 is disposed to surround one pixel group. The pixel group separation region 105 is formed between pixel groups adjacent to each other in a shape that penetrates or does not penetrate a Si substrate 102 (FIG. 5) in a depth direction thereof.

The pixel group separation region 105 is a region provided to electrically separate pixels and may be a region formed by implanting impurities or may be formed with a physical structure. The physical structure may be a structure formed by forming a trench or filling the trench with a predetermined material, for example, SiO2 or polysilicon. Further, the predetermined material may be a metal such as tungsten, which will be described later in another embodiment. By forming the pixel group separation region 105 with a metal, the pixel group separation region 105 can also function as a light shielding film that shields light from adjacent pixels so that color mixing can be reduced.

The pixel groups adjacent to each other are separated by the pixel group separation region 105. Pixels adjacent to each other in the pixel group are separated by a pixel separation region 103. The pixel separation region 103 is formed, for example, by filling a trench with polysilicon. The pixel separation region 103 is formed between the pixel 101a-1 and the pixel 101a-2, between the pixel 101a-1 and the pixel 101a-3, between the pixel 101a-2 and the pixel 101a-4, and between the pixel 101a-3 and the pixel 101a-4.

A transfer gate 111a of the transfer transistor 72 (FIG. 3) is formed in each pixel 101a. A transfer gate 111a-1 is formed in the pixel 101a-1, a transfer gate 111a-2 is formed in the pixel 101a-2, a transfer gate 111a-3 is formed in the pixel 101a-3, and a transfer gate 111a-4 is formed in the pixel 101a-4.

FIG. 5 is a vertical cross-sectional view of the pixel 101a according to the first embodiment of the pixel 101 to which the present technique is applied and corresponds to a position of line segment A-B in FIG. 4.

Although a case in which the pixel 101 described below is a backside illumination-type will be described as an example, the present technique can also be applied to a frontside illumination-type.

In the figure, the pixel 101a-1 that is a G pixel and the pixel 101a-2 that is an R pixel are illustrated as two pixels adjacent to each other. Since the pixel 101a-1 and the pixel 101a-2 have the same basic configuration, the pixel 101a-1 will be described as an example for the same portion.

The pixel 101a-1 has a PD 71-1 which is a photoelectric conversion element of each pixel formed inside the Si substrate 102. The PD 71 of the Si substrate 102 is an n-type impurity region, and a pn junction region 104 is formed in a comb shape in the n-type impurity region. Further, the pn junction region 104 is formed on side surfaces of the pixel separation region 103 formed in a comb shape.

The pixel separation region 103 is formed between the pixel 101a-1 and the pixel 101a-2 in a vertical direction in the figure and also in a horizontal direction thereof. A portion of the pixel separation region 103 formed in the vertical direction functions as a function of separating pixels. A portion of the pixel separation region 103 formed in the horizontal direction has a pn junction region 104 formed on the side surfaces and has a structure capable of increasing a charge storage capacity. The pixel separation region 103 is formed of, for example, polysilicon. In addition, the pixel separation region 103 is a p-type region.

In the pn junction region 104, a p-type solid phase diffusion layer and an n-type solid phase diffusion layer are formed in order from the pixel separation region 103 side toward the PD 71. The solid phase diffusion layers are layers in which a p-type layer and an n-type layer formed by impurity doping are formed using a manufacturing method which will be described later.

The pn junction region 104 includes the p-type solid phase diffusion layer and the n-type solid phase diffusion layer, and the pn junction region 104 forms a strong electric field region and holds charges generated in the PD 71. Also, although the pn junction region 104 will be described as a region in which the p-type solid phase diffusion layer and the n-type solid phase diffusion layer are stacked, a depletion layer may be formed between the p-type solid phase diffusion layer and the n-type solid phase diffusion layer, and in the following description, the pn junction region 104 will be described as also including a case in which there is a depletion layer.

The pixel group separation region 105 is formed between the pixel 101a-1 and a pixel (not shown) of a pixel group adjacent thereto. Similarly, the pixel group separation region 105 is formed between the pixel 101a-2 and a pixel (not shown) of a pixel group adjacent thereto.

As described above, the pixel group separation region 105 can be configured, for example, by forming SiO2 as a side wall film in a trench and filling the side wall film with polysilicon as a filling material. Also, SiN may be adopted as the side wall film instead of SiO2. Also, doped polysilicon may be used as the filling material instead of polysilicon. In a case in which the doped polysilicon is filled or in a case in which a n-type impurity or a p-type impurity is doped after the polysilicon is filled by applying a negative bias thereto, for example, of about −2 V, the dark characteristic can be further improved.

An insulating layer 106 is formed in a lower layer (on a lower side in the figure) of the Si substrate 102. A light shielding film 107 is formed on the insulating layer 106. The light shielding film 107 is provided to prevent light from leaking into adjacent pixels and is formed between PDs 71 adjacent to each other. Further, the light shielding film 107 is formed in the insulating layer 106 at a portion below the pixel separation region 103. The light shielding film 107 is made of, for example, a metal material such as tungsten (W).

A color filter (CF) 108 is formed on the insulating layer 106 on a back surface side of the Si substrate 102, and an on-chip lens (OCL) 109 that collects incident light onto the PD 71 is formed on the CF 108. The OCL 109 can be formed of an inorganic material, and for example, SiN, SiO, or SiOxNy (where 0<x≤1 and 0<y≤1) can be used.

Although not shown in FIG. 4, the configuration may also be such that a cover glass or a transparent plate such as a resin may be adhered on the OCL 76. Further, the CF 108 is provided with a plurality of color filters for each pixel and the configuration may be such that colors of the color filters can be arranged, for example, in a Bayer array. In the example shown in FIG. 5, a G (green) color filter is formed on the pixel 101a-1, which is a G pixel, and an R (red) color filter is formed in the pixel 101a-2 which is an R pixel.

An insulating film 110 is formed on a front surface side of the Si substrate 102, which is a side opposite to a light incident side of the PD 71 (this is the upper side in the figure and becomes the front surface side), and a wiring layer (not shown) is formed on the insulating film 110. A plurality of transistors are formed in the wiring layer. FIG. 5 shows an example in which the transfer gate 111 of the transfer transistor 72 is formed. The transfer gate 111 is formed of a vertical transistor. That is, in the transfer gate 111, a vertical type transistor trench 112 is opened, and the transfer gate 111 for reading a charge from the PD 71 is formed therein.

Further, although not shown, pixel transistors such as the reset transistor 74, the amplification transistor 75, and the selection transistor 76 are formed on the front surface side of the Si substrate 102.

A size of the pixel 101 can be, for example, 1 μm in lateral width and 3 μm in depth. The lateral width may be, for example, a distance between a center of the pixel separation region 103 and a center of the pixel group separation region 105 in FIG. 5, and this distance can be, for example, 1 μm. The depth can be, for example, a thickness of the Si substrate 102 in FIG. 5, and this thickness can be, for example, 3 μm.

Further, a thickness of one comb having the comb structure physically processed and formed in the PD 71 can be 200 nm (0.2 μm). The thickness of one comb is a thickness from a lower side to an upper side of the pn junction region 104, that is, a physically processed thickness of a protruding portion of the pixel separation region 103 in the lateral direction, in other words, a thickness of the polysilicon filled in the processed portion, and this thickness can be, for example, 200 nm.

Further, although FIG. 5 shows the case in which the portion of the comb structure has three combs, in other words, three protrusions, the number of the protrusions is not limited to three and may be any other number. As will be described later, the number can be set in accordance with the size of the pixel 101, in other words, the thickness of the Si substrate 102. That is, in a case in which the Si substrate 102 is thinner, the number of protrusions in the comb structure can be reduced, and in a case in which the Si substrate 102 is thicker, the number of protrusions in the comb structure can be increased.

As shown in FIG. 5, the pixel separation region 103 has a shape having protrusions in the horizontal direction in the figure from a center in the vertical direction (a center between the pixels). In other words, the pixel separation region 103 has a shape in which the pixel 101-1 and the pixel 101-2 each have protrusions. Further, the protrusions are formed to have linear shapes in the lateral direction.

The pn junction region 104 is formed on surfaces of the protrusions at the portions having the comb structure of the pixel separation region 103. This pn junction region 104 has an impurity concentration of about 10¹⁷ to 10¹⁸/cm³. Also, the pn junction region 104 is formed by solid phase diffusion or plasma doping.

Also, although the pn junction region 104 can be formed using an impurity implantation method (ion implantation), it has a concentration gradient in the depth direction of the pixel 101 when formed using the impurity implantation method. For example, in the pixel 101a shown in FIG. 5, in a case in which the three protrusions are a first protrusion, a second protrusion, and a third protrusion in order from the top in the figure, a concentration of the pn junction region 104 of the first protrusion, a concentration of the pn junction region 104 of the second protrusion, and a concentration of the pn junction region 104 of the third protrusion may differ from each other.

Further, in a case in which the pn junction region 104 is formed using the impurity implantation method, the first protrusion and the third protrusion have different depths in the pixel, and thus a concentration difference between the concentration of the pn junction region 104 of the first protrusion and the concentration of the pn junction region 104 of the third protrusion may be increased.

Further, when forming the pn junction region 104 in a protrusion on a deeper side, it is necessary to perform implantation with high energy, and thus formation of the pn junction region 104 in the protrusion on the deeper side is more difficult than when forming the pn junction region 104 of a protrusion on a shallower side.

For these reasons, in the case in which the pn junction region 104 is formed using the impurity implantation method, it is difficult to form a uniform p-type region or n-type region at a desired concentration, it is difficult to form a steep pn junction, and thus sufficient sensitivity improvement is not easily achieved.

In the case in which the pn junction region 104 is formed using solid phase diffusion or plasma doping, the concentration gradient can be made substantially uniform in the depth direction of the pixel. In this case, the concentration of the pn junction region 104 of the first protrusion, the concentration of the pn junction region 104 of the second protrusion, and the concentration of the pn junction region 104 of the third protrusion can be formed substantially uniformly.

Therefore, by forming the pn junction region 104 using solid phase diffusion or plasma doping, it is possible to form a uniform p-type region or n-type region at a desired concentration, and it is possible to form a steep pn junction region so that sufficient improvement in sensitivity can be realized.

In the pixel 101a shown in FIG. 5, the pixel separation region 103 is a p-type, the pn junction region 104 is formed around the p-type pixel separation region 103, and an n-type Si substrate 102 is formed around the pn junction region 104. By applying a negative bias (for example, −2 V) to the pixel separation region 103 and setting the Si substrate 102 side to zero bias, a steep electric field gradient from p to n can be obtained so that the charge storage capacity can be improved.

The charge generated in the PD 71 is carried from the p-type region to the n-type region and transferred to the floating diffusion (not shown in FIG. 5) region via the vertical type transistor 112 and the transfer gate 111. In FIG. 5, electrons are represented by “e” and their movements are represented by arrows.

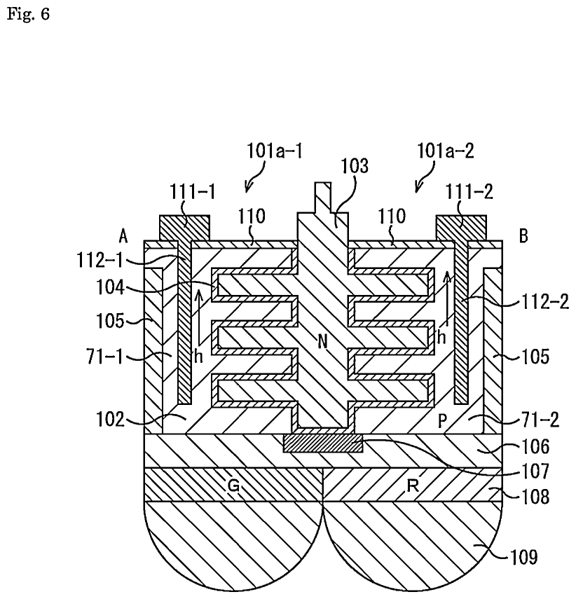

Here, a configuration of a case in which electrons are read is shown, but this may be a configuration in which holes are read. FIG. 6 shows a configuration of the pixel 101a in the case in which holes are read. The pixel 101a for reading holes and the pixel 101a for reading electrons shown in FIG. 5 have the same configuration but are different from each other in that the pixel separation region 103 is formed of an n-type impurity region and the Si substrate 102 is formed of a p-type impurity region.

Further, the case of the pixel 101a for reading holes is different in that a positive bias (for example, +2V) is applied to the pixel separation region 103. The Si substrate 102 is applied with zero bias. By being configured in this way, holes generated in the PD 71 are carried from the n-type region to the p-type region and transferred to the floating diffusion (not shown in FIG. 6) region via the vertical type transistor 112 and the transfer gate 111. In FIG. 6, holes are represented by “h” and their movements are represented by arrows.

Although a configuration in which electrons are read will be described below as an example in the following description like the pixel 101a shown in FIG. 5, the present technique can also be applied to a configuration in which holes are read like the pixel 101a shown in FIG. 6.

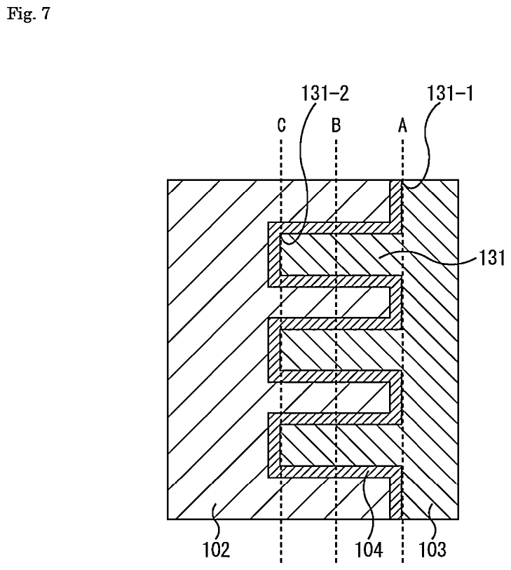

Here, a description on portions of the protrusions of the pixel separation region 103 will be added with reference to FIG. 7. In the following description, the portions of the protrusions of the pixel separation region 103 will be referred to as a protruding portion 131.

The protruding portion 131 may be a protruding portion or a recessed portion depending on where a surface described as a reference, hereinafter referred to as a reference surface, is set. Further, since the pn junction region 104 is formed at the protruding portion 131, it can be said that the pn junction region 104 is a region having an uneven structure. This uneven structure is formed in the Si substrate 102. Therefore, the reference surface can be a predetermined surface of the Si substrate 102, and here, a case in which a portion of the Si substrate 102 is used as the reference surface will be described below as an example.

FIG. 7 is an enlarged view of the vicinity of the protruding portion 131. A surface of the protruding portion 131, which is a boundary portion of the protruding portion 131 with the pn junction region 104 and is closer to the pixel separation region 103 side, will be referred to as a right side surface 131-1. Also, a surface of the protruding portion 131, which is a boundary portion of the protruding portion 131 with the pn junction region 104 and is closer to the Si substrate 102, will be referred to as a left side surface 131-2.

It is assumed that a reference surface A is a surface in which the right side surface 131-1 is formed and a reference surface C is a surface in which the left side surface 131-2 is formed. Further, it is assumed that a reference surface B is a surface located between the reference surfaces A and C, in other words, the reference surface B is a surface located between the right side surface 131-1 and the left side surface 131-2.

In a case in which the reference plane A is used as the reference, a shape of the protruding portion 131 becomes a shape having a protruding portion with respect to the reference surface A. That is, in the case in which the reference surface A is used as the reference, the left side surface 131-2 is located at a position protruding to the left with respect to the reference surface A (=right side surface 131-1), and the protruding portion 131 becomes a region in which a protruding portion is formed.

In a case in which the reference surface C is used as the reference, the shape of the protruding portion 131 becomes a shape having a recessed portion with respect to the reference surface C. That is, in the case in which the reference surface C is used as the reference, the right side surface 131-1 is located at a position recessed to the right with respect to the reference surface C(=left side surface 131-2), and the protruding portion 131 becomes a region in which a recessed portion is formed.

In a case in which the reference surface B is used as the reference, the shape of the protruding portion 131 becomes a shape having a recessed portion and a protruding portion with respect to the reference surface B. That is, in the case in which the reference surface B is used as the reference, the left side surface 131-2 is located at a position protruding to the left with respect to the reference surface B (=a surface at an intermediary position between the right side surface 131-1 and the left side surface 131-2), and the protruding portion 131 can be said to be a region in which a protruding portion is formed.

On the other hand, in the case in which the reference plane B is used as the reference, the right side surface 131-1 is located at a position recessed to the right with respect to the reference surface B, and the protruding portion 131 can be said to be a region in which a recessed portion is formed.

Thus, in the cross-sectional view of the pixel 101, the protruding portion 131 is a region which can be expressed as a region formed by a recessed portion, a region formed by a protruding portion, or a region formed by a recessed portion and a protruding portion, depending on where the reference surface is set.

In the following description, the protruding portion 131 will be described on the basis of the case in which the reference surface A, that is, the right side surface 131-1, is used as the reference surface, and the description will be continued assuming that it is a region in which a protruding portion is formed.

As shown in FIG. 7, the pn junction region 104 is formed on side surfaces of the protruding portion 131 of the pixel separation region 103, in other words, on the Si substrate 102 in contact with the protruding portion 131. Since the plurality of protruding portions 131 are formed in the PD 71, a plurality of pn junction regions 104 having protruding shapes are formed in the PD 71. In this way, by forming the plurality of pn junction regions 104 having protruding shapes in the PD 71, the charge storage capacity of the PD 71 can be increased.

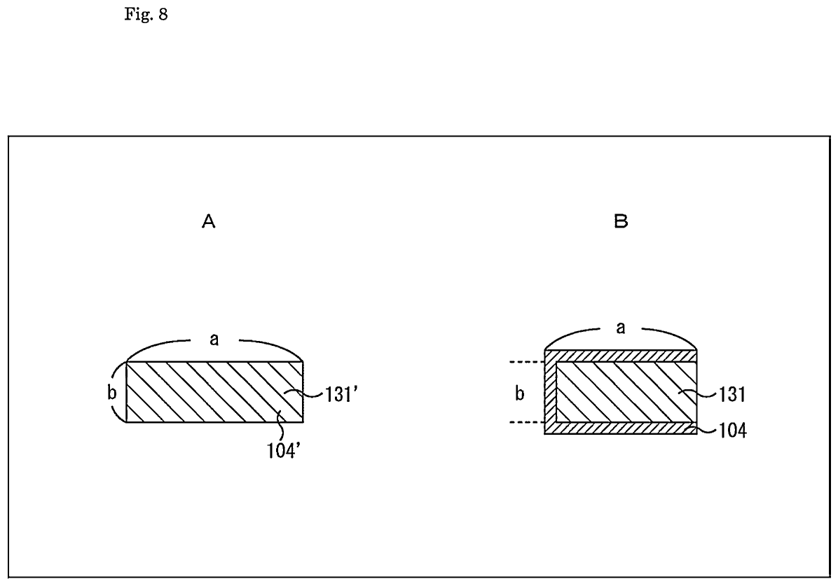

Increasing the charge storage capacity of the PD 71 will be described with reference to FIG. 8. FIG. 8A shows an area of a pn junction region 104′ where the entire protruding portion 131′ (hereinafter, described with a dash to distinguish it from the protruding portion 131 to which the present embodiment is applied) is the pn junction region 104′, and FIG. 8B is a diagram showing an area of the pn junction region 104 when the pn junction region 104 is formed around the protruding portion 131 by adopting the present technique.

As shown in FIG. 8A, in a case in which a horizontal length of the pn junction region 104′ is a length a (the unit is nm, and the same applies below) and a vertical length thereof is a length b, a size (an area) of the pn junction region 104′ becomes ab.

On the other hand, as shown in FIG. 8B, in a case in which the pn junction region 104 is formed around the protruding portion 131, the pn junction region 104 includes two sides having the length a and one side having the length b, and thus the area of the pn junction region 104 becomes 2a+b.

For example, in a case in which a=2 and b=1, the area of the pn junction region 104′=ab=2 and the area of the pn junction region 104=2a+b=5. Further, for example, in a case in which a=4 and b=2, the area of the pn junction region 104′=ab=8 and the area of the pn junction region 104=2a+b=10.

In any case, the area of the pn junction region 104 in the case to which the present technique is applied as shown in FIG. 8B becomes larger than the area of the pn junction region 104′ in the case to which the present technique is not applied as shown in FIG. 8A. The pn junction region 104 is a pn junction having a sharp concentration change, and the area of such a pn junction region 104 can be enlarged so that the charge storage capacity can be increased. Also, it is possible to increase a dynamic range thereof.

<Regarding Manufacturing of Pixel>

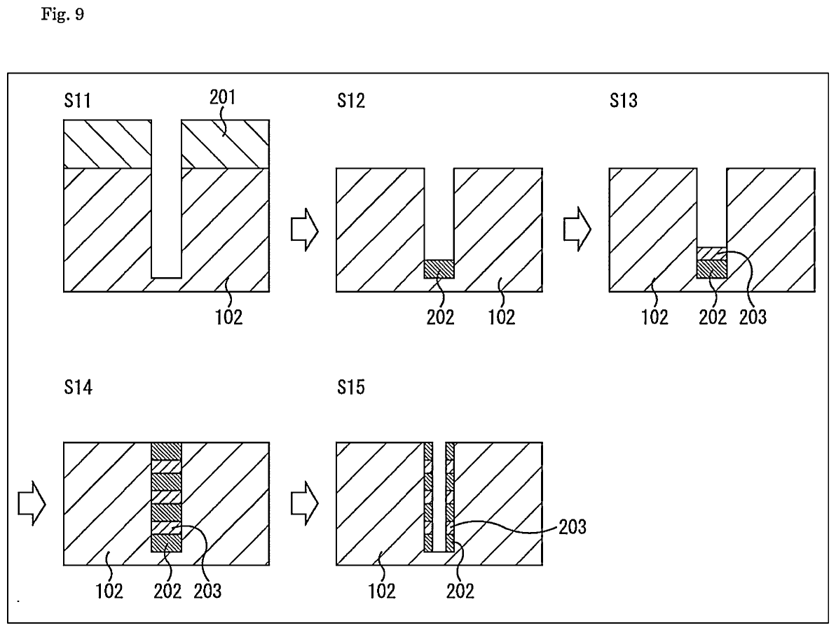

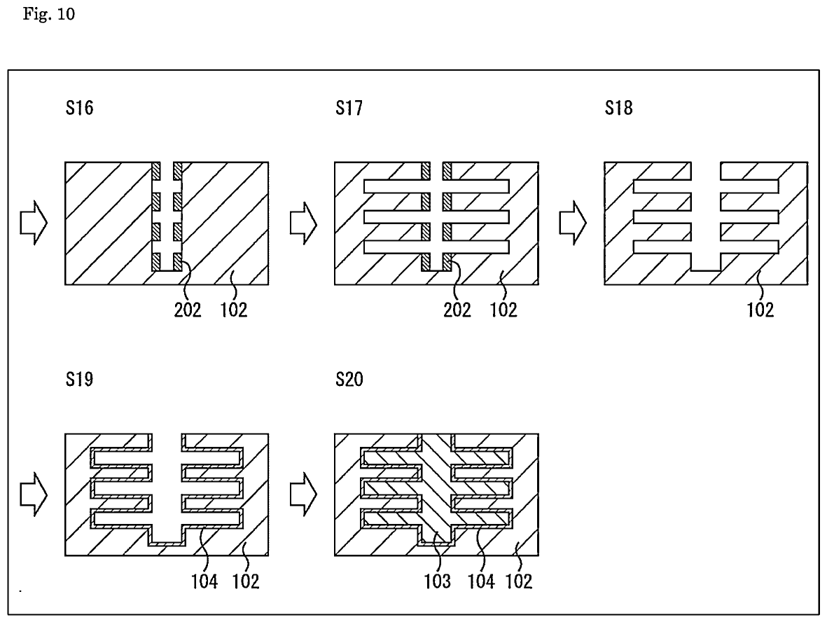

Next, manufacturing of the pixel 101a, particularly manufacturing of the protruding portion 131 and the pn junction region 104, will be described with reference to FIGS. 9 and 10.

In step S11, a vertical groove having a predetermined size is formed in the Si substrate 102. For the Si substrate 102, for example, a Si(111) substrate is used. A resist (PR) mask 201 opened with a width of a groove to be formed is applied onto the Si substrate 102, a CF-based mixed gas is used, and dry etching is performed with low damage. The width of the groove, which is opened in the PR mask 201, can be 200 nm, for example.

In step S12, the PR mask 201 is removed after the vertical groove is formed. After the PR mask 201 is removed, a SiO2 film is formed on the Si substrate 102 using, for example, chemical vapor deposition (CVD). Further, etching is performed and a Si surface is exposed. This state is a state in which the SiO2 film remains in the vertical groove.

In order to make the SiO2 film in the groove have a predetermined thickness, the SiO2 film is etched to a predetermined thickness using a PR mask and a CF-based mixed gas that can etch only SiO2. For example, as shown in step S12 of FIG. 9, a SiO2 film 202 having a predetermined film thickness is formed at a bottom portion of the groove. A film thickness of the SiO2 film 202 can be 500 nm, for example.

In step S13, a PR mask or an organic film is formed on the Si substrate 102. After forming a film, etching is performed and the Si substrate 102 is exposed. This state is a state in which the PR mask or the organic film remains in the groove. Here, the description will be continued assuming that the organic film is formed.

In order to make the organic film in the groove have a predetermined thickness, the organic film is dry-etched using a PR mask and using a gas that can etch only the organic film until the organic film has a predetermined thickness. For example, as shown in step S13 of FIG. 9, an organic film 203 having a predetermined film thickness is formed on the SiO2 film 202 in the groove. A thickness of the organic film 203 can be 200 nm, for example.

In step S14, the SiO2 film 202 and the organic film 203 are repeatedly formed to fill the inside of the groove. That is, by repeating the processes in step S12 and step S13, the SiO2 film 202 and the organic film 203 are repeatedly formed and the SiO2 film 202 and the organic film 203 are alternately stacked in the groove.

In step S15, a vertical groove is formed in a multilayer film in which the SiO2 film 202 and the organic film 203 are alternately stacked. A PR mask is used, and a groove having a width narrower than the vertical groove formed in step S11, for example, a width of 150 nm, is formed by dry etching.

In step S16 (FIG. 10), the organic film 203 is removed by performing ashing. As shown in step S16 of FIG. 10, the organic film 203 is removed, and thus it is in a state in which only the SiO2 film 202 remains on a side wall of the groove.

In step S17, etching is performed using the SiO2 film 202 remaining on the side wall of the vertical groove as a mask. In step S17, wet etching using an alkaline aqueous solution such as KOH (potassium hydroxide) is performed. Due to this etching, the Si substrate 102 is selectively etched in the horizontal direction.

By performing the etching, horizontal grooves which become the protruding portions 131 are formed. This horizontal groove can be formed with a size of, for example, about 600 nm.

In step S18, the SiO2 film 202 on the side wall in the vertical groove is removed using, for example, a solution of hydrofluoric acid or the like.

In step S19, the pn junction region 104 is formed on the Si substrate 102 through solid phase diffusion of boron or phosphorus. Alternatively, the pn junction region 104 is formed by diffusing boron or phosphorus into the Si substrate 102 using plasma doping.

In the case of forming the pn junction region 104 through the solid phase diffusion, a SiO2 film containing P (phosphorus) that is an n-type impurity is formed inside the opened groove. Through this film formation, the SiO2 film is formed on each side wall of the vertical groove and the horizontal grooves. After the SiO2 film is formed, heat treatment, for example, annealing at 1000° C., is performed to dope P (phosphorus) from the SiO2 film to the Si substrate 102 side.

After the doping, the formed SiO2 film containing P is removed, and then heat treatment is performed again to diffuse P (phosphorus) up to the inside of the Si substrate 70, whereby an n-type solid phase diffusion layer self-aligned with the current groove shape, in this case, with the grooves formed in the vertical and horizontal directions, is formed.

Next, a SiO2 film containing B (boron) that is a p-type impurity is formed inside the groove, then heat treatment is performed and B (boron) is solid-phase diffused from the SiO2 film to the Si substrate 70 side, whereby a p-type solid phase diffusion layer self-aligned with the shape of the groove is formed.

After that, the SiO2 film containing B (boron) formed on an inner wall of the groove is removed.

By going through the above steps, the pn junction region 104 including the n-type solid phase diffusion layer and the p-type solid phase diffusion layer can be formed along the shape of the groove, in this case, along the shape of the pixel separation region 103.

In step S20, the hollow vertical groove and horizontal grooves are filled with a predetermined filler such as polysilicon.

As described above, a plurality of pn junction regions 104 are formed in one pixel with low damage.

<Structure of Pixel in Second Embodiment>

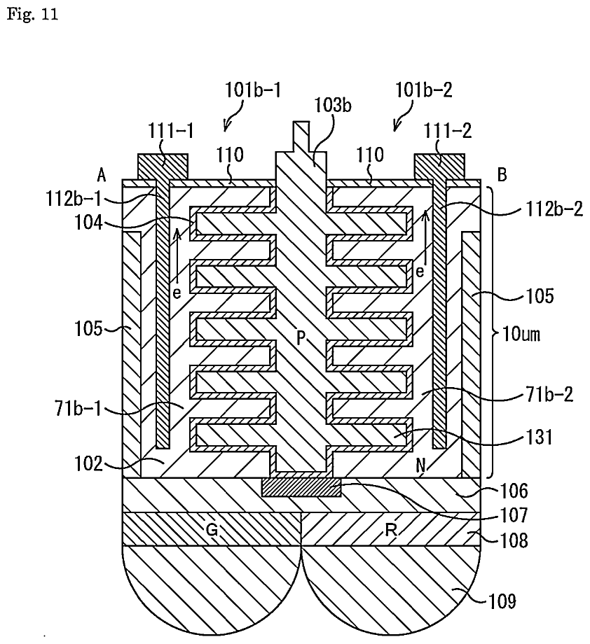

FIG. 11 is a diagram showing a configuration example of the pixel 101b in a second embodiment. Since a basic configuration of the pixel 101b shown in FIG. 11 is the same as that of the pixel 101a shown in FIG. 5, the same portions are denoted by the same reference numerals, and descriptions thereof will be omitted.

The difference is that a size of a PD 71b of the pixel 101b shown in FIG. 11 is larger than that of a PD 71a (hereinafter, the PD 71 of the pixel 101a is referred to as the PD 71a) of the pixel 101a shown in FIG. 5.

Referring again to the pixel 101a shown in FIG. 5. the case in which the depth of the PD 71a of the pixel 101a (the vertical length in the figure) is, for example, about 3 μm and the number of combs of the comb structure in the pixel separation region 103, that is, the number of protruding portions 131 is three has been illustrated. On the other hand, in the pixel 101b shown in FIG. 11, the depth (the vertical length in the figure) of the PD 71b is configured to be, for example, about 10 μm.

By making the PD 71b deeper, the number of combs, that is, the number of protruding portions 131, of the comb structure in the pixel separation region 103 can be increased, and as shown in FIG. 11, for example, five can be formed. By increasing the number of protruding portions 131, the number of pn junction regions 104 formed on the side surfaces of the protruding portions 131 is also increased, and thus the charge storage capacity can be further increased.

Further, since the PD 71b is formed to be deeper, the vertical type transistor 112b is also formed to be deeper. For example, in a case in which the PD 71b is configured to be about 10 μm, the vertical type transistor 112b is configured to be about 9.5 μm. Also, the depth of the vertical transistor 12b may not have the value illustrated here as long as electrons generated in a surface layer on an incident light side can be extracted without leakage.

As described above, the deep PD 71b is suitable for application to, for example, an image sensor that receives light having a long wavelength such as infrared rays. Although the case in which the CF 108 is G (green) and R (red) has been illustrated in FIG. 11, the CF 108 includes color filters suitable for the colors to be received.

Similar to the pixel 101a according to the first embodiment, also in the pixel 101b according to the second embodiment, the area of the pn junction region 104 having a sharp concentration change can be increased, and the charge storage capacity can be increased. In addition, it is also possible to increase the dynamic range.

<Structure of Pixel in Third Embodiment>

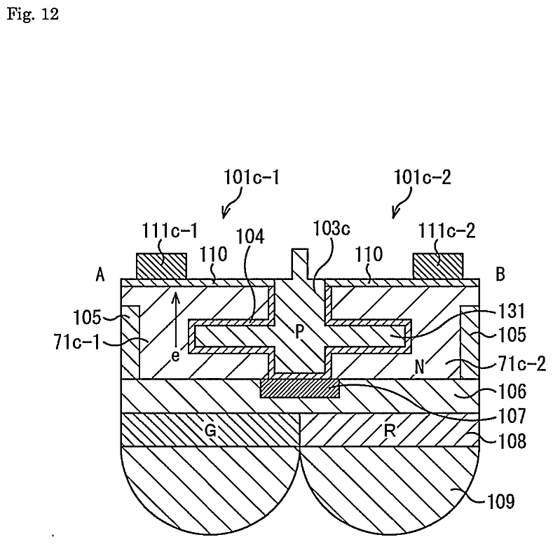

FIG. 12 is a diagram showing a configuration example of a pixel 101c according to a third embodiment. Since a basic structure of the pixel 101c shown in FIG. 12 is the same as that of the pixel 101a shown in FIG. 5, the same portions are denoted by the same reference numerals, and descriptions thereof will be omitted.

The difference is that a size of a PD 71c of the pixel 101c shown in FIG. 12 is smaller than that of the PD 71a of the pixel 101a shown in FIG. 5.

In the pixel 101c shown in FIG. 12, since the PD 71c is formed to have a shallow depth (the vertical length in the figure), the number of combs, that is, the number of protruding portions 131, of the comb structure in the pixel separation region 103 is formed to be smaller. FIG. 12 shows an example in which one protruding portion 131 is formed. Further, by forming the PD 71c shallow, a configuration in which the vertical type transistor 112 may not be formed can be obtained. The pixel 101c shown in FIG. 12 is configured such that the transfer transistor includes a transfer gate 111c and there is no vertical transistor 111.

As described above, by forming the PD 71c to be shallower, a height of the pixel 101c can be reduced. When the PD 71c is formed to be shallower, the number of combs (the number of protruding portions 131) of the comb structure in the pixel separation region 103 may be reduced, but as described with reference to FIG. 8, the area of the pn junction region 104 can be formed to be larger than that of the PD 71 to which the present technique is not applied.

Therefore, also in the pixel 101c according to the third embodiment, similar to the pixel 101a according to the first embodiment, it is possible to increase the area of the pn junction region 104 having a sharp concentration change, and thus the charge storage capacity can be increased. Further, it is also possible to increase the dynamic range.

<Structure of Pixel in Fourth Embodiment>

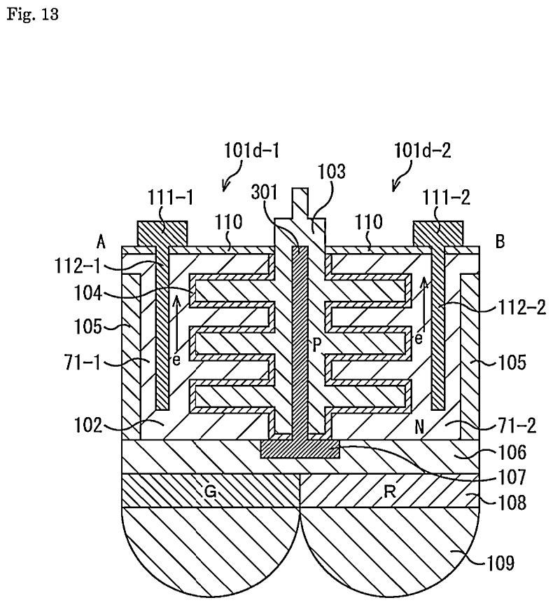

FIG. 13 is a diagram showing a configuration example of a pixel 101d according to a fourth embodiment. Since a basic configuration of the pixel 101d shown in FIG. 13 is the same as that of the pixel 101a shown in FIG. 5, the same portions are denoted by the same reference numerals, and descriptions thereof will be omitted.

The pixel separation region 103 of the pixel 101d shown in FIG. 13 is different from that of the pixel 101a shown in FIG. 5 in that it has a configuration in which a light shielding wall 301 for more surely shielding light leaking from adjacent pixels is added.

The vertical groove of the pixel separation region 103 of the pixel 101d is filled with polysilicon and a metal such as tungsten (W) or an oxide film such as SiO2, which has a light shielding characteristic. The portion filled with the material having the light shielding characteristic functions as a light shielding wall 301 that shields stray light from adjacent pixels.

The light shielding wall 301 has a length the same as or slightly shorter than the Si substrate 102, and for example, in a case in which the Si substrate 102 is formed to have a depth of about 3 μm, the light shielding wall 301 can be formed to have a length of 3 μm or less, for example, about 2.7 μm. Also, the length of the light shielding wall 301 may of course be a value other than the numerical values exemplified here as long as it can effectively prevent color mixing.

As described above, by providing the light shielding wall 301, color mixing between pixels can be further inhibited. In addition, similar to the pixel 101a according to the first embodiment, also in the pixel 101d according to the fourth embodiment, it is possible to increase the area of the pn junction region 104 having a sharp concentration change, and the charge storage capacity can be increased. Further, it is also possible to increase the dynamic range.

Also, although the case, in which the light shielding wall 301 is provided in the pixel 101a according to the first embodiment, has been described here as an example, the configuration may be such that the pixel 101b according to the second embodiment is provided with the light shielding wall 301, or the pixel 101c according to the third embodiment is provided with the light shielding wall 301.

<Structure of Pixel in Fifth Embodiment>

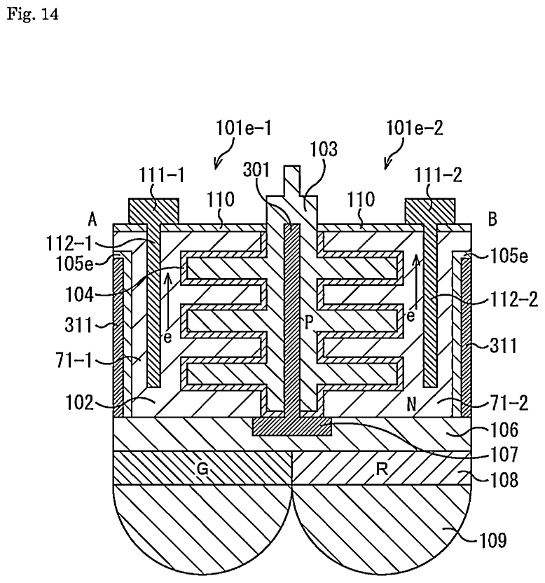

FIG. 14 is a diagram showing a configuration example of a pixel 101e according to a fifth embodiment. Since a basic configuration of the pixel 101e shown in FIG. 14 is the same as that of the pixel 101d shown in FIG. 13, the same portions are denoted by the same reference numerals, and descriptions thereof will be omitted.

The pixel separation region 103 of the pixel 101e shown in FIG. 14 is distinguished in that a light shielding wall 311 is added to the pixel group separation region 105 of the pixel 101d according to the embodiment shown in FIG. 13, and the other parts are the same.

A pixel group separation region 105e of the pixel 101e is filled with a metal such as tungsten (W) or an oxide film such as SiO2. The portion filled with the material having the light shielding characteristic functions as a light shielding wall 311 that shields stray light from pixels of adjacent pixel groups.

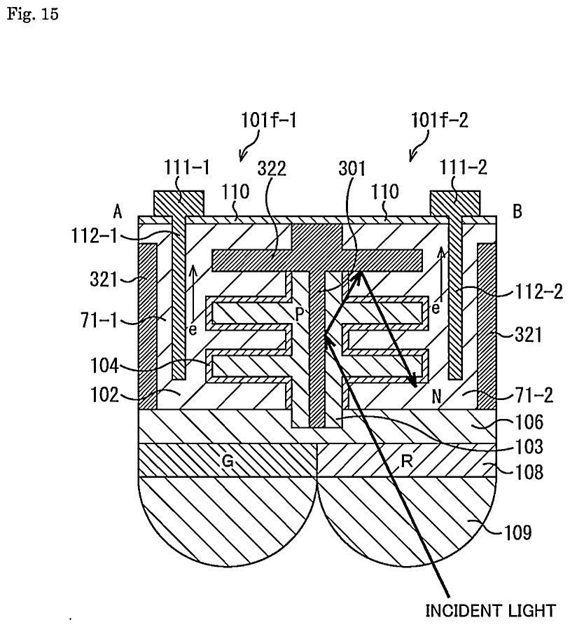

In a case in which the pixel group separation region 105e is, for example, a region formed by implanting impurities, such an impurity region may remain and the light shielding wall 311 may be formed in the impurity region. Alternatively, the pixel group separation region 105 may be formed by the light shielding wall 311 (a light shielding wall 321 in FIG. 15) like a pixel 101f, which will be described later as a sixth embodiment.

For example, in a case in which the Si substrate 102 is formed to have a depth of about 3 μm, the light shielding wall 311 can be formed to have a length slightly shorter than the Si substrate 102, for example, about 2.7 μm. Also, the length of the light shielding wall 311 may of course be a value other than the numerical values exemplified here as long as it can effectively prevent color mixing.

As described above, by providing the light shielding wall 311, color mixing between pixels (pixel groups) can be further inhibited. In addition, similar to the pixel 101a according to the first embodiment, also in the pixel 101e according to the fifth embodiment, it is possible to increase the area of the pn junction region 104 having a sharp concentration change, and the charge storage capacity can be increased. Further, it is also possible to increase the dynamic range.

Also, although the case in which the light shielding wall 311 is provided in the pixel 101d according to the fourth embodiment has been described here as an example, the configuration may be such that any of the pixels 101a to 101c according to the first to third embodiments is provided with the light shielding wall 311. That is, the configuration may be such that the pixel group separation region 105 of the pixel 101 not provided with the light shielding wall 311 in the pixel separation region 103 is provided with the light shielding wall 311.

<Structure of Pixel in Sixth Embodiment>

FIG. 15 is a diagram showing a configuration example of a pixel 101f according to a sixth embodiment. Since a basic configuration of the pixel 101f shown in FIG. 15 is the same as to that of the pixel 101e shown in FIG. 14, the same portions are designated by the same reference numerals, and descriptions thereof will be omitted.

The pixel group separation region 105 of the pixel 101f shown in FIG. 15 is different from the pixel 101d shown in FIG. 14 in that it is formed only with the light shielding wall 321. In the pixel 101f, the pixel group separation region 105 is formed of a metal such as tungsten (W) or an oxide film such as SiO2. Since the material having the light shielding characteristic is filled, it functions as the light shielding wall 321 that shields stray light from adjacent pixels.

Further, the light shielding wall 301 is formed in the vertical direction of the pixel separation region 103 of the pixel 101f shown in FIG. 15, similarly to the pixel 101e (FIG. 14). Further, a light shielding layer 322 is formed at the portion of the comb (protruding portion) formed on the deepest side (a side opposite to a light incident surface side and the wiring layer side) from the light incident surface side of the comb structure in the pixel separation region 103 of the pixel 101f. Like the light shielding wall 301, the light shielding layer 322 is also formed of a metal such as tungsten (W) or an oxide film such as SiO2 and has a light shielding characteristic and shields light leaking to the wiring layer side.

As shown in FIG. 15, the PD 71 of the pixel 101f has the light shielding wall 301, the light shielding wall 321, and the light shielding layer 322 formed respectively on three sides other than the light incident surface side in a cross-sectional view. Therefore, stray light from adjacent pixels can be shielded, and the influence of color mixing can be reduced.

Further, as shown by the arrows in FIG. 15, the light is reflected by the light shielding wall so that the light leaking to the adjacent pixels or wiring layer side if there is no light shielding wall can be made incident on the PD 71, and thus the amount of incident light that enters the PD 71 can be increased.

With reference to FIG. 15, for example, light obliquely incident on a pixel 101f-2 is shielded by the light shielding wall 301 without leaking to a pixel 101f-1 and is reflected by the light shielding wall 301 into the pixel 101f-2. The reflected light reflected by the light shielding wall 301 is further reflected by the light shielding layer 322 into the pixel 101f-2 without leaking to the wiring layer side.

Since the incident light is reflected by such a light shielding wall (light shielding layer), the reflected light can also be captured in the PD 71 (pn junction region 104). Therefore, it is possible to improve oblique incidence characteristics thereof and to increase an optical path length of the incident light, and thus detection sensitivity thereof can be improved, and the amount of received light can be increased.

In addition, similar to the pixel 101a according to the first embodiment, also in the pixel 101f according to the sixth embodiment, it is possible to increase the area of the pn junction region 104 having a sharp concentration change, and the charge storage capacity can be increased. Further, it is also possible to increase the dynamic range.

<Structure of Pixel in Seventh Embodiment>

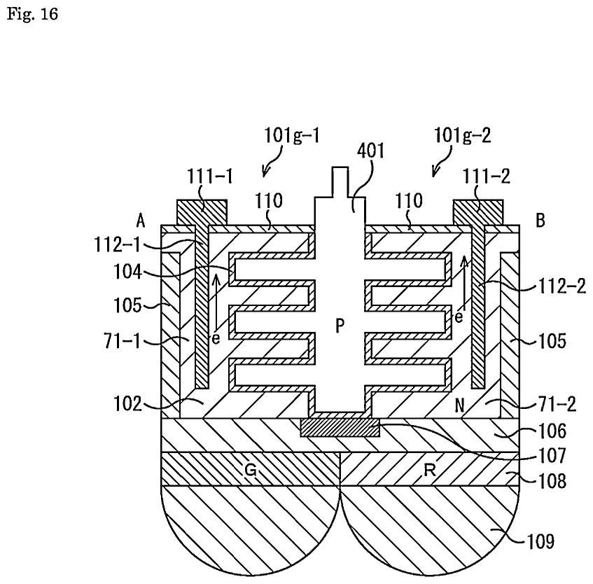

FIG. 16 is a diagram showing a configuration example of a pixel 101g according to a seventh embodiment. Since a basic structure of the pixel 101g shown in FIG. 16 is the same as that of the pixel 101a shown in FIG. 5, the same portions are designated by the same reference numerals, and descriptions thereof will be omitted.

The pixel 101g shown in FIG. 16 is different from the pixel 101a shown in FIG. 5 in that a pixel separation region 401 is filled with a transparent material (a material that transmits light). For the transparent material with which the pixel separation region 401 is filled, for example, Indium Tin Oxide (ITO), Indium Zinc Oxide (IZO), or the like can be used.

Referring again to the pixel 101a shown in FIG. 5, the pixel separation region 103 of the pixel 101a is filled with, for example, polysilicon as a material thereof. Some of the light that has entered from the OCL 109 side is absorbed by polysilicon, and an amount of light that reaches the pn junction region 104 formed in the protruding portion 131 may be reduced.

According to the pixel 101g shown in FIG. 16, since the pixel separation region 401 of the pixel 101a is filled with a transparent material, the light incident from the OCL 109 side can pass through the pixel separation region 401 and reach the pn junction region 104 formed in the protruding portion 131. Therefore, the amount of light reaching the pn junction region 104 can be increased, and the charge storage capacity can be increased. Further, it is also possible to increase the dynamic range.

The number of protruding portions 131 may be increased by applying the pixel 101b of the second embodiment (FIG. 11) to the pixel 101g of the seventh embodiment. Further, the configuration may be such that, by applying the pixel 101c of the third embodiment (FIG. 12) to the pixel 101g of the seventh embodiment, the number of the protruding portions 131 is reduced, and the vertical type transistor 112 may not be formed.

<Structure of Pixel in Eighth Embodiment>

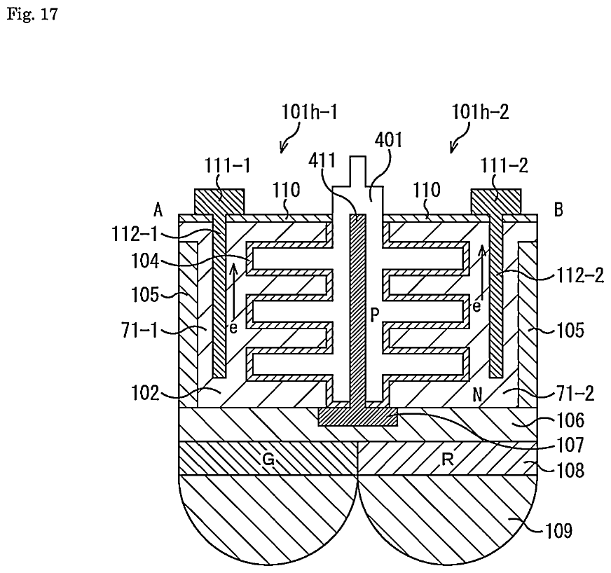

FIG. 17 is a diagram showing a configuration example of a pixel 101h according to an eighth embodiment. Since a basic configuration of the pixel 101h shown in FIG. 17 is the same as that of the pixel 101g shown in FIG. 16, the same portions are denoted by the same reference numerals, and descriptions thereof will be omitted.

The pixel 101h shown in FIG. 17 is different from the pixel 101g shown in FIG. 16 in that a light shielding wall 411 for surely shielding light leaking from adjacent pixels is added to the pixel separation region 401.

A vertical groove of the pixel separation region 401 of the pixel 101h is filled with a transparent material (hereinafter, ITO will be described as an example) and a metal such as tungsten (W) or an oxide film such as SiO2, which has a light shielding characteristic. The portion filled with the material having the light shielding characteristic functions as the light shielding wall 411 that shields stray light from adjacent pixels.

The light shielding wall 411 can be formed to have a length the same as or slightly shorter than the Si substrate 102, and for example, in a case in which the Si substrate 102 is formed to have a depth of about 3 μm, the light shielding wall 411 can also be formed to have a length of 3 μm or less, for example, about 2.7 μm. Also, the length of the light shielding wall 411 may of course be a value other than the numerical values exemplified here as long as it can effectively prevent color mixing.

In a case in which the pixel separation region 401 is made of the transparent material as described above, leakage of light into adjacent pixels may increase, but by providing the light shielding wall 411, color mixing between pixels can be inhibited, and the charge storage capacity in the pixel can be increased.

In addition, similar to the pixel 101a according to the first embodiment, also in the pixel 101h according to the eighth embodiment, it is possible to increase the area of the pn junction region 104 having a sharp concentration change, and the charge storage capacity can be increased. Further, it is also possible to increase the dynamic range.

<Structure of Pixel in Ninth Embodiment>

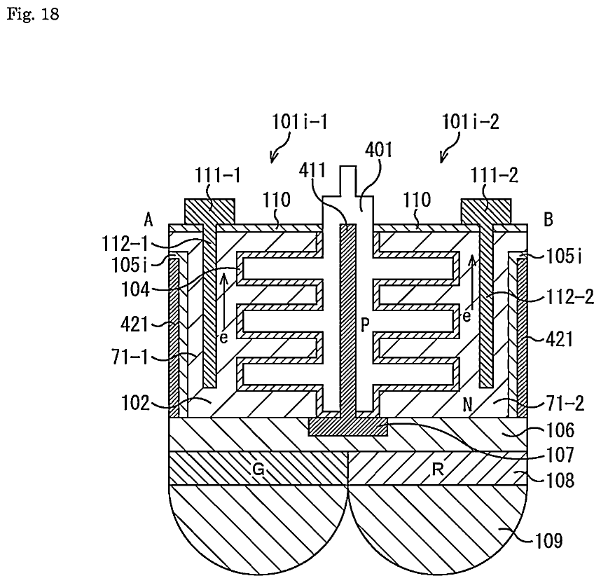

FIG. 18 is a diagram showing a configuration example of a pixel 101i according to a ninth embodiment. Since a basic configuration of the pixel 101i shown in FIG. 18 is the same as that of the pixel 101h shown in FIG. 17, the same portions are denoted by the same reference numerals, and descriptions thereof will be omitted.

The pixel separation region 103 of the pixel 101i shown in FIG. 18 is distinguished in that a light shielding wall 421 is added to the pixel group separation region 105 of the pixel 101h according to the embodiment shown in FIG. 17, and the other parts are the same.

The pixel group separation region 105i of the pixel 101i is filled with a metal such as tungsten (W) or an oxide film such as SiO2. The portion filled with the material having the light shielding characteristic functions as the light shielding wall 421 that shields stray light from adjacent pixels.

In a case in which the pixel group separation region 105i is, for example, a region formed by implanting impurities, such an impurity region may remain and the light shielding wall 421 may be formed in the impurity region.

The light shielding wall 421 can be formed to have a length slightly shorter than that of the Si substrate 102, and for example, in a case in which the Si substrate 102 is formed to have a depth of about 3 μm, the light shielding wall 421 can be formed to have a length of about 2.7 μm, for example. Also, the length of the light shielding wall 421 may of course be a value other than the numerical values exemplified here as long as it can effectively prevent color mixing.

As described above, by providing the light shielding wall 411 and the light shielding wall 421, color mixing between pixels and between pixel groups can be inhibited. Further, by forming the pixel separation region 401 with the transparent material such as IOT, incident light can be more received.

In addition, similar to the pixel 101a according to the first embodiment, also in the pixel 101i according to the ninth embodiment, it is possible to increase the area of the pn junction region 104 having a sharp concentration change, and the charge storage capacity can be increased. Further, it is also possible to increase the dynamic range.

<Structure of Pixel in Tenth Embodiment>

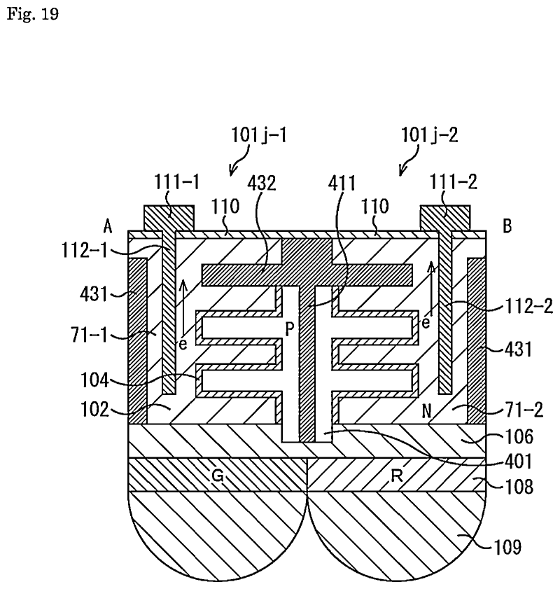

FIG. 19 is a diagram showing a configuration example of a pixel 101j according to a tenth embodiment. Since a basic configuration of the pixel 101j shown in FIG. 19 is the same as that of the pixel 101i shown in FIG. 18, the same portions are denoted by the same reference numerals, and descriptions thereof will be omitted.

The pixel 101j shown in FIG. 19 is different from the pixel 101h shown in FIG. 18 in that the pixel group separation region 105 is formed only with a light shielding wall 431. In the pixel 101j, the pixel group separation region 105 is formed of a metal such as tungsten (W) or an oxide film such as SiO2. Since the material having the light shielding characteristic is filled, it functions as the light shielding wall 431 that shields stray light from pixels of adjacent pixel groups.

Also, the light shielding wall 411 is formed in the vertical direction of the pixel separation region 401 of the pixel 101j shown in FIG. 19, as in the pixel 101i (FIG. 18). Further, a light shielding layer 432 is formed at the portion of the comb (protruding portion) formed on the deepest side (a side opposite to the light incident surface side and the wiring layer side) from the light incident surface side of the comb structure in the pixel separation region 401 of the pixel 101j. Like the light shielding wall 411, the light shielding layer 432 is also formed of a metal such as tungsten (W) or an oxide film such as SiO2, has a light shielding characteristic, and shields light leaking to the wiring layer side.

As shown in FIG. 19, the PD 71 of the pixel 101j has the light shielding wall 411, the light shielding wall 431, and the light shielding layer 432 formed respectively on three sides other than the light incident surface side in a cross-sectional view. Therefore, even when the pixel separation region 401 is made of a transparent material, stray light from adjacent pixels can be shielded and the influence of color mixing can be reduced.

Further, as in the pixel 101f shown in FIG. 15, the light is reflected by the light shielding wall and the light shielding layer, light leaking to adjacent pixels or the wiring layer side can be made incident on the PD 71 if there is no light shielding wall or light shielding layer, and thus the amount of incident light that enters the PD 71 can be increased.

For example, light obliquely incident on a pixel 101j-2 is shielded by the light shielding wall 411 without leaking to a pixel 101j-1 and reflected by the light shielding wall 411 into the pixel 101j-2. The reflected light reflected by the light shielding wall 411 is further reflected by the light shielding layer 432 into the pixel 101j-2 without leaking to the wiring layer side.

Since the incident light is reflected by such a light shielding wall or light shielding layer, the reflected light can also be captured in the PD 71 (pn junction region 104). Therefore, it is possible to improve the oblique incidence characteristics and to increase the optical path length of the incident light, and thus the detection sensitivity can also be improved and the amount of received light can be increased.

In addition, similar to the pixel 101a according to the first embodiment, also in the pixel 101j according to the tenth embodiment, it is possible to increase the area of the pn junction region 104 having a sharp concentration change, and the charge storage capacity can be increased. Further, it is also possible to increase the dynamic range.

<Structure of Pixel in Eleventh Embodiment>

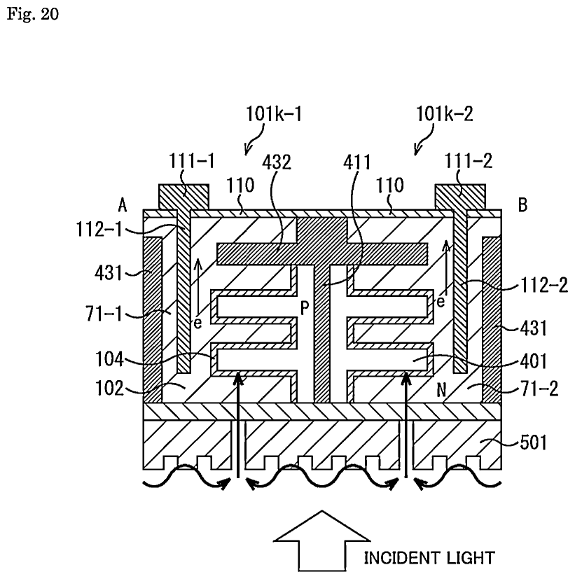

FIG. 20 is a diagram showing a configuration example of a pixel 101k according to an eleventh embodiment. Since a basic configuration of the pixel 101k shown in FIG. 20 is the same as that of the pixel 101j shown in FIG. 19, the same portions are denoted by the same reference numerals, and descriptions thereof will be omitted.

The pixel 101k shown in FIG. 20 is different from the pixel 101j shown in FIG. 19 in that a plasmon filter 501 is provided in place of the color filter 108 and the OCL 109, and the other parts are the same.

The plasmon filter 501 is an optical filter that transmits narrow band light having a predetermined narrow wavelength band (narrow band). Also, the plasmon filter 501 is a kind of thin metal film filter that uses a thin film made of a metal such as aluminum and is a narrow band filter that uses surface plasmons.

FIG. 20 shows a cross-sectional view of the plasmon filter 501 having a grating structure. The plasmon filter 501 having the grating structure is a thin film made of a metal, and one having a grating structure (several tens of nanometers to 100 nm) can be used therefor. In the plasmon filter 501 having the grating structure, a wavelength to be selected (transmitted) is set in accordance with a size of the grating structure.

The plasmon filter 501 having the grating structure is configured such that a standing wave of incident light is generated on the surface, and the generated standing wave passes through through-holes to the photodiode 71 side. The holes formed in the plasmon filter 501 can have a diameter of about 100 nm, for example.

For example, in a case in which the color filter 108 and the OCL 109 are provided as in the pixel 101j shown in FIG. 19, film thicknesses of the color filter 108 and the OCL 109 are about 1 μm to 2 μm, but the plasmon filter 501 can be formed to have a film thickness of 1 μm to 2 μm or less, the height of the pixel can be reduced.

In addition, by reducing the height, color mixing can be further inhibited. Further, by positioning the holes in the region in which the pn junction region 104 is formed, the incident light can be efficiently guided to the pn junction region 104, and the sensitivity can be further improved.

Although the plasmon filter 501 having the grating structure has been described as an example here, a hole array structure, a dot array structure, or a structure having a shape called a Bull's eye can be applied to the plasmon filter 501.

Further, although the case in which the plasmon filter 501 is applied to the pixel 101j of the tenth embodiment has been described here as an example, the plasmon filter 501 may be applied to the pixels 101a to 101i according to the first to ninth embodiments.

Similar to the pixel 101a according to the first embodiment, also in the pixel 101k according to the eleventh embodiment, it is possible to increase the area of the pn junction region 104 having a sharp concentration change, and the charge storage capacity can be increased. Further, it is also possible to increase the dynamic range.

<Structure of Pixel in Twelfth Embodiment>

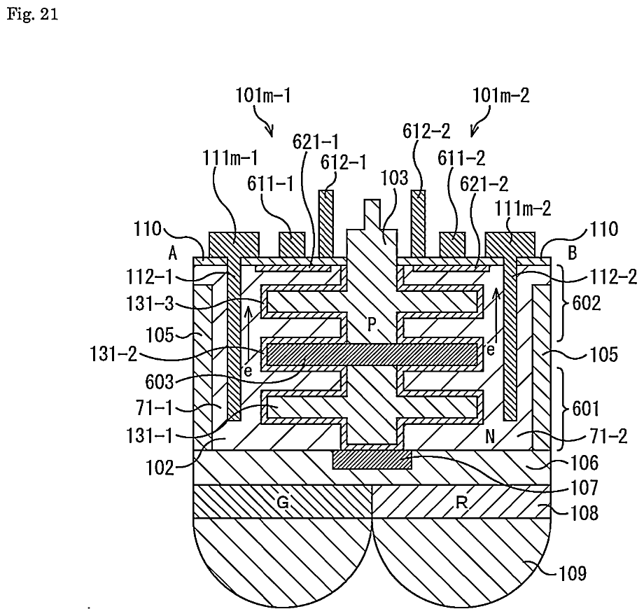

FIG. 21 is a diagram showing a configuration example of a pixel 101m according to a twelfth embodiment. Since a basic configuration of the pixel 101m shown in FIG. 21 is the same as that of the pixel 101a shown in FIG. 5, the same portions are denoted by the same reference numerals, and descriptions thereof will be omitted.

The pixel 101m shown in FIG. 21 is different from the pixel 101a shown in FIG. 5 in that it has a light receiving region 601 and a memory region 602. The light receiving region 601 is a region that receives light incident from the OCL 109 side and accumulates charges. The memory region 602 temporarily holds the charges accumulated in the light receiving region 601. By providing the light receiving region 601 and the memory region 602, a global shutter function can be added.

According to the global shutter function, since sequential reading is possible after performing simultaneous reading of all pixels in the memory region 602, an exposure timing can be made common to each pixel, and image distortion can be inhibited.

The pixel 101m is configured to have the light receiving region 601 and the memory region 602 in one pixel, and a light shielding layer 603 is provided between the light receiving region 601 and the memory region 602 in order to divide one pixel into the light receiving region 601 and the memory region 602.

The light shielding layer 603 is formed at a position that divides the pixel 101m in the vertical direction. The pixel 101m shown in FIG. 21 has protruding portions 131-1 to 131-3, and the light shielding layer 603 is formed at the position of the protruding portion 131-2.

The light shielding layer 603 is formed by filling the portion of the protruding portion 131-2 of the pixel separation region 103 with tungsten (W) or an oxide film. The light shielding layer 603 has a function of shielding light and a function of preventing charges from leaking from the light receiving region 601 to the memory region 602. Any material that can realize such functions can be used for the material of the light shielding layer 603.

The pixel 101m has a vertical transistor 111m for transferring the charges accumulated in the light receiving region 601 to the memory region 602. The charges read by the vertical transistor 111m are written in the memory region 602 by a write gate 611. The charges written in the memory region 602 (accumulated charges) are read by a read gate 612 and transferred to the amplification transistor 75 (FIG. 3).

In the memory region 602 of the pixel 101m, a pn junction region 621 is formed near a region in which the write gate 611 and the read gate 612 are formed and is configured such that a charge retention capacity of the memory region 602 can be maintained and improved.

Although the configuration in which the pixel 101a of the first embodiment is combined with the twelfth embodiment and the configuration to provide the light receiving region 601 and the memory region 602 in one pixel has been described here as an example, it is also possible to combine the twelfth embodiment with any of the second to eleventh embodiments and to have a configuration in which the pixels 101b to k include the light receiving region 601 and the memory region 602.

Similar to the pixel 101a according to the first embodiment, also in the pixel 101m according to the twelfth embodiment, it is possible to increase the area of the pn junction region 104 having a sharp concentration change, and the charge storage capacity of the light receiving region 601 can be increased. Further, it is also possible to increase the dynamic range. Further, by providing the light receiving region 601 and the memory region 602, the global shutter function can be realized and images in which distortion is inhibited can be captured.

<Structure of Pixel in Thirteenth Embodiment>

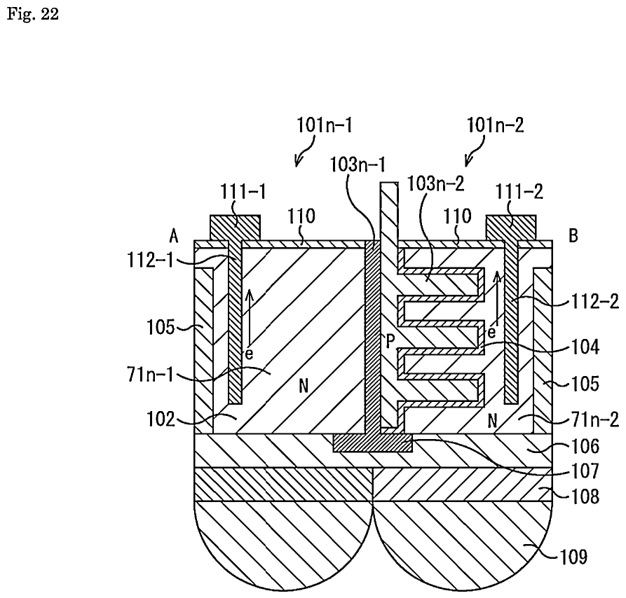

FIG. 22 is a diagram showing a configuration example of a pixel 101n according to a thirteenth embodiment.

The pixel 101n according to the thirteenth embodiment includes the PD having the comb structure (hereinafter, referred to as a comb-shaped PD) and a PD to which the comb structure is not applied (hereinafter, described as a non-comb-shaped PD), and one pixel group is formed by the two pixels having different shapes.

In FIG. 22, a pixel 101n-1 shown on a left side in the figure is formed of a non-comb-shaped PD 71n-1 and a pixel 101n-2 shown on a right side in the figure is formed of a comb-shaped PD 71n-2. A pixel separation region 103n-1 is formed between the non-comb-shaped PD 71n-1 and the comb-shaped PD 71n-2. The pixel separation region 103n-1 has a structure continuous with the light shielding film 107 and is formed of, for example, tungsten or an oxide film.

The pixel separation region 103n-1 is provided between the non-comb-shaped PD 71n-1 and the comb-shaped PD 71n-2 to prevent charges from leaking out and to prevent stray light. A pixel separation region 103n-2 is also formed between the non-comb-shaped PD 71n-1 and the comb-shaped PD 71n-2. This pixel separation region 103n-2 has protruding portions 131 and is configured as a region filled with a material such as polysilicon, like the pixel separation region 103 of the pixel 101a according to the first embodiment.

As described above, by configuring one pixel group with the non-comb-shaped PD 71n and the comb-shaped PD 71n, the pixels (two pixels in this case) constituting the one pixel group can be formed with pixels having different charge storage capacities. The comb-shaped PD 71n has a larger charge storage capacity than the non-comb-shaped PD 71n.

By using such a difference in charge storage capacity, the configuration may be such that, for example, the comb-shaped PD 71n having a large charge storage capacity is used for a pixel that receives a color that is easily saturated, and the non-comb-shaped PD 71n is used for a pixel that receives a color that is difficult to saturate. For example, in a case in which a R (Red) pixel, a G (Green) pixel, and a B (Blue) pixel are disposed in a Bayer array, the R pixel can be formed of the comb-shaped PD 71n since the R pixel is more likely to be saturated than the G pixel and the B pixel, and the G pixel and the B pixel can include the non-comb-shaped PD 71n.

Although the example in which the pixel 101a according to the first embodiment is combined with the thirteenth embodiment to configure one pixel group with the non-comb-shaped PD 71n and the comb-shaped PD 71n has been described here, the configuration may be such that the thirteenth embodiment is combined with any one of the second to twelfth embodiments to configure the pixels 101b to 101n to include the non-comb-shaped PD 71n and the comb-shaped PD 71n.

<Structure of Pixel in Fourteenth Embodiment>

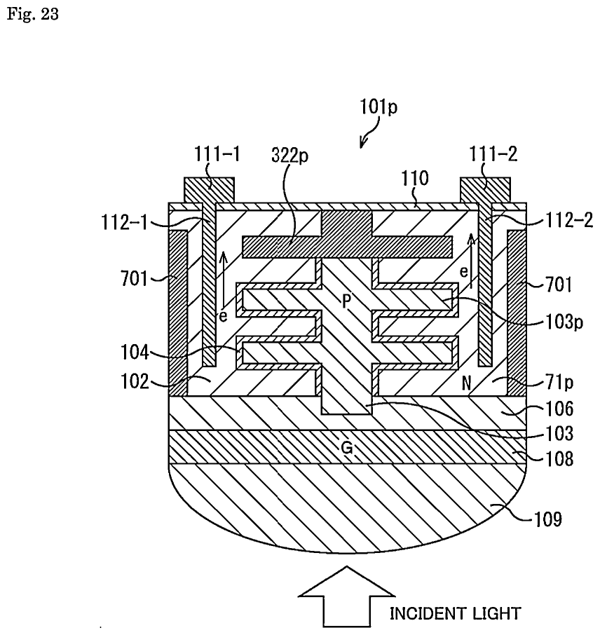

FIG. 23 is a diagram showing a configuration example of a pixel 101p according to a fourteenth embodiment.

The case in which two pixels form one pixel group and the two pixels have the comb-shaped pn junction region 104 has been exemplified to explain the pixel 101 according to the first to twelfth embodiments described above. As shown in FIG. 23, it is also possible to adopt a configuration in which one pixel 101p has the comb-shaped pn junction region 104.

A PD 71p of the pixel 101p shown in FIG. 23 has a central axis and a comb-shaped pn junction region 104p having protruding portions 131p on the left and right around the central axis in one pixel. In this way, by providing the comb-shaped pn junction region 104p in one pixel 101p, it is possible to increase the area of the pn junction region 104p having a sharp concentration change, and the charge storage capacity can be increased. Further, it is also possible to increase the dynamic range.

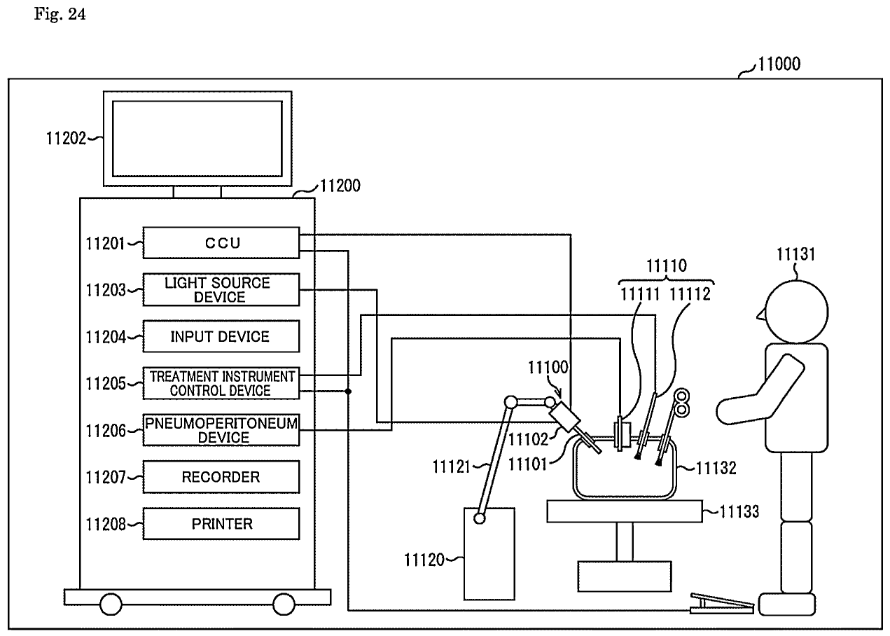

In the pixel 101p shown in FIG. 24, a light shielding layer 322p is formed on the wiring layer side (upper side in the figure), as in the pixel 101f (FIG. 15) according to the sixth embodiment. Further, in the embodiment described above, an inter-pixel separation region 701 is formed at a portion corresponding to the pixel group separation region 105. This inter-pixel separation region 701 is formed to separate adjacent pixels 101p therefrom and is formed using tungsten, an oxide film, or the like as a material thereof. With such a configuration, the oblique incidence characteristics can be improved, the optical path length of incident light can be increased, and the detection sensitivity can be improved.

The pixels 101a to 101n according to the first to thirteenth embodiments can be configured as one pixel like the pixel 101p according to the fourteenth embodiment. For example, a transparent material such as IOT may be filled as the material of the pixel separation region 103p of the pixel 101p shown in FIG. 23.

According to the present technique, a plurality of steep pn junction regions can be formed in the depth direction of the pixel. Further, since the plurality of steep pn junction regions are formed in the depth direction of the pixel, the charge storage capacity can be increased. For these reasons, the sensitivity can be significantly improved even in a fine pixel. Moreover, it is possible to increase the dynamic range.

Also, when the plurality of steep pn junction regions are formed in the depth direction of the pixel, the pn junction regions are not formed by impurity implantation, and thus the pn junction regions can be easily formed even at deeper positions of the pixel. Further, concentrations of a p-type impurity and a n-type impurity in the formed pn junction regions can be formed uniformly. Further, since it is not formed by impurity implantation, it is possible to reduce damage to the substrate that may occur during impurity implantation, and thus occurrence of white spots or white scratches can be inhibited, and deterioration of image quality can be prevented.

<Application Example to Endoscopic Surgery System>

Further, for example, the technique according to the present disclosure (the present technique) may be applied to an endoscopic surgery system.

FIG. 24 is a diagram showing an example of a schematic configuration of an endoscopic surgery system to which the technique according to the present disclosure (the present technique) may be applied.

FIG. 24 illustrates a situation in which an operator (doctor) 11131 is performing an operation on a patient 11132 on a patient bed 11133 using an endoscopic surgery system 11000. As illustrated, the endoscopic surgery system 11000 includes an endoscope 11100, other surgical instruments 11110 such as a pneumoperitoneum tube 11111 and an energy treatment instrument 11112, a support arm device 11120 that supports the endoscope 11100, and a cart 11200 equipped with various devices for endoscopic surgery.

The endoscope 11100 includes a lens barrel 11101 of which a region having a predetermined length from a tip is inserted into a body cavity of the patient 11132, and a camera head 11102 connected to a base end of the lens barrel 11101. In the illustrated example, the endoscope 11100 configured as a so-called rigid mirror having the rigid lens barrel 11101 is illustrated, but the endoscope 11100 may be configured as a so-called flexible mirror having a flexible lens barrel.

An opening into which an objective lens is fitted is provided at a tip of the lens barrel 11101. A light source device 11203 is connected to the endoscope 11100, and light generated by the light source device 11203 is guided to the tip of the lens barrel by a light guide extending to the inside the lens barrel 11101 and radiated toward an observation target in the body cavity of the patient 11132 via the objective lens. Also, the endoscope 11100 may be a direct-viewing endoscope, or may be a perspective or side-viewing endoscope.

An optical system and an image sensor are provided inside the camera head 11102, and the reflected light (observation light) from the observation target is condensed on the image sensor by the optical system. The observation light is photoelectrically converted by the image sensor, and an electric signal corresponding to the observation light, that is, an image signal corresponding to an observed image is generated. The image signal is transmitted to a camera control unit (CCU) 11201 as RAW data.

The CCU 11201 includes a central processing unit (CPU), a graphics processing unit (GPU), and the like, and integrally controls operations of the endoscope 11100 and a display device 11202. Further, the CCU 11201 receives the image signal from the camera head 11102 and performs various image processing such as development processing (demosaic processing) on the image signal for displaying an image based on the image signal.

The display device 11202 displays an image based on the image signal subjected to the image processing by the CCU 11201 under the control of the CCU 11201.

The light source device 11203 includes a light source such as a light emitting diode (LED) and supplies the endoscope 11100 with irradiation light for imaging a surgical site or the like.

An input device 11204 is an input interface for the endoscopic surgery system 11000. A user can input various kinds of information and instructions to the endoscopic surgery system 11000 via the input device 11204. For example, the user inputs an instruction to change imaging conditions (type of irradiation light, magnification, focal length, etc.) for the endoscope 11100.

A treatment instrument control device 11205 controls driving of an energy treatment instrument 11112 for cauterization of tissue, incision, sealing of blood vessel, or the like. A pneumoperitoneum device 11206 sends gas into the body cavity through a pneumoperitoneum tube 11111 in order to inflate the body cavity of the patient 11132 for the purpose of securing a visual field for the endoscope 11100 and a working space for the operator. A recorder 11207 is a device capable of recording various information regarding surgery. A printer 11208 is a device that can print various types of information regarding surgery in various formats such as text, images, or graphs.

In addition, the light source device 11203 that supplies the endoscope 11100 with the irradiation light for imaging the surgical site can include, for example, an LED, a laser light source, or a white light source composed of a combination thereof. In a case in which a white light source includes a combination of RGB laser light sources, an output intensity and an output timing of each color (each wavelength) can be controlled with high accuracy, and thus the light source device 11203 can adjust a white balance of a captured image. Further, in this case, the observation target is irradiated with laser light from each of the RGB laser light sources in a time division manner, and the driving of the image sensor of the camera head 11102 is controlled in synchronization with the irradiation timing, whereby it is also possible to time-divisionally capture an image corresponding to each of RGB. According to this method, a color image can be obtained without providing a color filter on the image sensor.

Also, the driving of the light source device 11203 may be controlled to change an intensity of the output light at predetermined time intervals. By controlling the driving of the image sensor of the camera head 11102 in synchronization with the timing of changing the intensity of the light to acquire images in a time division manner and combine the images, it is possible to generate an image with a high dynamic range without so-called black underexposure and overexposure.

Further, the light source device 11203 may be configured to be able to supply light in a predetermined wavelength band corresponding to special light observation. In the special light observation, for example, wavelength dependence of light absorption in body tissues is utilized and light having a narrower band than irradiation light (that is, white light) at the time of normal observation is radiated, whereby a so-called narrow band light observation (narrow band imaging) is performed in which a predetermined tissue such as a blood vessel on a surface of a mucous membrane is imaged with high contrast. Alternatively, in the special light observation, fluorescence observation in which an image is obtained from the fluorescence generated by irradiating excitation light may be performed. In the fluorescence observation, it is possible to irradiate the body tissue with excitation light and observe the fluorescence from the body tissue (autofluorescence observation), to obtain a fluorescence image by locally injecting a reagent such as indocyanine green (ICG) into the body tissue and irradiating the body tissue with excitation light corresponding to the fluorescence wavelength of the reagent, or the like. The light source device 11203 may be configured to be able to supply the narrow band light and/or the excitation light corresponding to such special light observation.

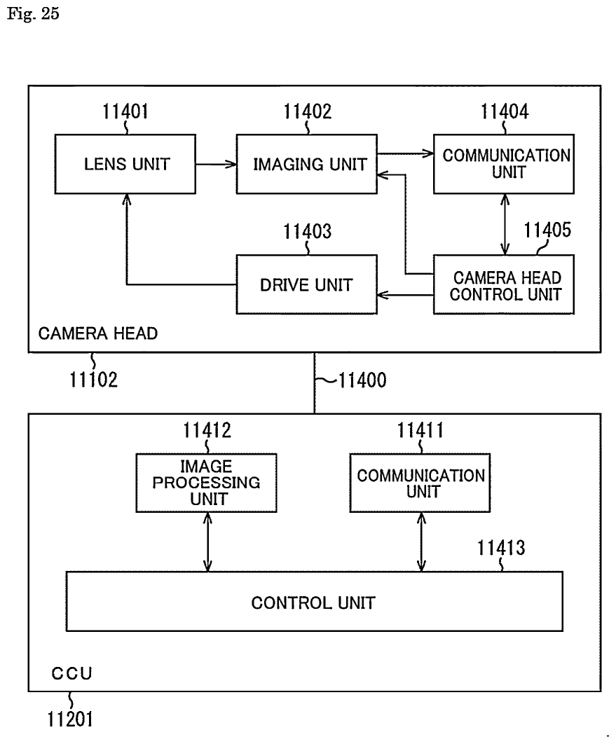

FIG. 25 is a block diagram showing an example of a functional configuration of the camera head 11102 and CCU 11201 shown in FIG. 24.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 is connected to the CCU 11201 to be able to communicate with each other via a transmission cable 11400.

The lens unit 11401 is an optical system provided at a connection portion with the lens barrel 11101. The observation light captured from the tip of the lens barrel 11101 is guided to the camera head 11102 and enters the lens unit 11401. The lens unit 11401 is configured by combining a plurality of lenses including a zoom lens and a focus lens.

The number of image sensors forming the imaging unit 11402 may be one (so-called single-plate type) or plural (so-called multi-plate type). In a case in which the imaging unit 11402 is configured as the multi-plate type, for example, image signals corresponding respectively to RGB are generated by each image sensor, and a color image may be obtained by combining them. Alternatively, the imaging unit 11402 may be configured to include a pair of image sensors for respectively acquiring right-eye image signals and left-eye image signals corresponding to 3D (dimensional) display. By performing the 3D display, the operator 11131 can understand a depth of a living tissue in the operation site more accurately. Also, in a case in which the imaging unit 11402 is configured as the multi-plate type, a plurality of lens units 11401 may be provided corresponding to each image sensor.

Further, the imaging unit 11402 does not necessarily have to be provided in the camera head 11102. For example, the imaging unit 11402 may be provided inside the lens barrel 11101 immediately behind the objective lens.

The drive unit 11403 includes an actuator and moves the zoom lens and the focus lens of the lens unit 11401 by a predetermined distance along an optical axis thereof under the control of the camera head control unit 11405. Thus, a magnification and a focus of an image captured by the imaging unit 11402 can be appropriately adjusted.

The communication unit 11404 includes a communication device for transmitting and receiving various information to and from the CCU 11201. The communication unit 11404 transmits an image signal obtained from the imaging unit 11402 as RAW data to the CCU 11201 via the transmission cable 11400.

Further, the communication unit 11404 receives a control signal for controlling driving of the camera head 11102 from the CCU 11201 and supplies it to the camera head control unit 11405. The control signal includes information regarding imaging conditions such as, for example, information that specifies a frame rate of the captured image, information that specifies an exposure value at the time of capturing, and/or information that specifies the magnification and focus of the captured image.

Also, the imaging conditions such as the frame rate, the exposure value, the magnification, and the focus may be appropriately specified by the user, or may be automatically set by the control unit 11413 of the CCU 11201 on the basis of the acquired image signal. In the latter case, the so-called AE (auto exposure) function, AF (auto focus) function, and AWB (auto white balance) function are provided to the endoscope 11100.

The camera head control unit 11405 controls driving of the camera head 11102 on the basis of a control signal from the CCU 11201 received via the communication unit 11404.

The communication unit 11411 includes a communication device for transmitting and receiving various information to and from the camera head 11102. The communication unit 11411 receives an image signal transmitted from the camera head 11102 via the transmission cable 11400.

Further, the communication unit 11411 transmits a control signal for controlling driving of the camera head 11102 to the camera head 11102. The image signal and the control signal can be transmitted via electric communication, optical communication, or the like.

The image processing unit 11412 performs various types of image processing on the image signal that is the RAW data transmitted from the camera head 11102.

The control unit 11413 performs various controls regarding imaging of the surgical site or the like performed by the endoscope 11100 and display of a captured image obtained by imaging the surgical site or the like. For example, the control unit 11413 generates a control signal for controlling driving of the camera head 11102.

Further, the control unit 11413 causes the display device 11202 to display the captured image of the surgical site or the like on the basis of the image signal on which the image processing unit 11412 has performed the image processing. In this case, the control unit 11413 may recognize various objects in the captured image using various image recognition techniques. For example, the control unit 11413 can detect shapes and colors of edges of an object included in the captured image, thereby recognizing surgical instruments such as forceps, a specific living body part, bleeding, mist at the time of using the energy treatment instrument 11112, and the like. The control unit 11413 may use the recognition results to superimpose and display various types of surgery support information on the image of the surgical site when the captured image is displayed on the display device 11202. By displaying the surgery support information in a superimposed manner and presenting it to the operator 11131, a burden on the operator 11131 can be reduced, and the operator 11131 can reliably proceed with the surgery.

The transmission cable 11400 that connects the camera head 11102 to the CCU 11201 is an electric signal cable compatible with electric signal communication, an optical fiber compatible with optical communication, or a composite cable of these.

Here, in the illustrated example, wired communication is performed using the transmission cable 11400, but the communication between the camera head 11102 and the CCU 11201 may be performed wirelessly.

Also, although the endoscopic surgery system has been described here as an example, the technique according to the present disclosure may be applied to, for example, a microscopic surgery system or the like.

<Application Example to Mobile Object>

Also, for example, the technology according to the present disclosure may be realized as a device mounted on any type of mobile object such as automobiles, electric vehicles, hybrid electric vehicles, motorcycles, bicycles, personal mobilities, airplanes, drones, ships, robots, etc.

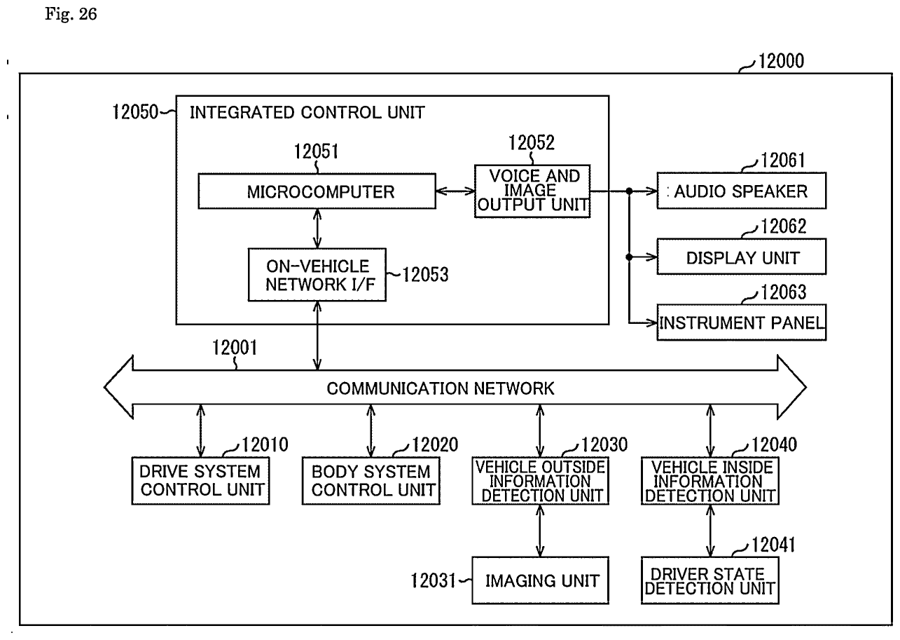

FIG. 26 is a block diagram showing a schematic configuration example of a vehicle control system that is an example of a mobile object control system to which the technology according to the present disclosure can be applied.

The vehicle control system 12000 includes a plurality of electronic control units connected via a communication network 12001. In the example shown in FIG. 26, the vehicle control system 12000 includes a drive system control unit 12010, a body system control unit 12020, a vehicle outside information detection unit 12030, a vehicle inside information detection unit 12040, and an integrated control unit 12050. Further, as functional constituents of the integrated control unit 12050, a microcomputer 12051, a voice and image output unit 12052, and an on-vehicle network I/F (Interface) 12053 are shown.

The drive system control unit 12010 controls operations of devices related to a drive system of a vehicle in accordance with various programs. For example, the drive system control unit 12010 functions as a control device for a driving force generation device for generating a driving force of a vehicle such as an internal combustion engine or a drive motor, a driving force transmission mechanism for transmitting a driving force to wheels, a steering mechanism that adjusts a steering angle of a vehicle, a braking device that generates a braking force for a vehicle, etc.

The body system control unit 12020 controls operations of various devices mounted on a vehicle body in accordance with various programs. For example, the body system control unit 12020 functions as a control device for a keyless entry system, a smart key system, a power window device, or various lamps such as headlamps, back lamps, brake lamps, winkers or fog lamps. In this case, the body system control unit 12020 may receive radio waves transmitted from a portable device that substitutes for a key or signals from various switches. The body system control unit 12020 receives inputs of these radio waves or signals and controls a vehicle door lock device, a power window device, lamps, and the like.

The vehicle outside information detection unit 12030 detects information outside the vehicle equipped with the vehicle control system 12000. For example, an imaging unit 12031 is connected to the vehicle outside information detection unit 12030. The vehicle outside information detection unit 12030 causes the imaging unit 12031 to capture an image outside the vehicle and receives the captured image. The vehicle outside information detection unit 12030 may perform object detection processing or distance detection processing with respect to people, vehicles, obstacles, signs, or characters on a road on the basis of the received image.

The imaging unit 12031 is an optical sensor that receives light and outputs an electrical signal in accordance with an amount of received light. The imaging unit 12031 can output the electric signal as an image or as ranging information. The light received by the imaging unit 12031 may be visible light or invisible light such as infrared rays.

The vehicle inside information detection unit 12040 detects information inside the vehicle. For example, a driver state detection unit 12041 that detects a state of a driver is connected to the vehicle inside information detection unit 12040. The driver state detection unit 12041 includes, for example, a camera that images the driver, and the vehicle inside information detection unit 12040 may calculate a degree of fatigue or a degree of concentration of the driver on the basis of detection information input from the driver state detection unit 12041, or may determine whether the driver is asleep or not.

The microcomputer 12051 can calculate a control target value of a driving force generation device, a steering mechanism or a braking device on the basis of information on the inside and outside of the vehicle acquired by the vehicle outside information detection unit 12030 or the vehicle inside information detection unit 12040 and output a control command to the drive system control unit 12010. For example, the microcomputer 12051 can perform cooperative control for the purpose of realizing a function of Advanced Driver Assistance System (ADAS) including vehicle collision avoidance or impact mitigation, follow-up traveling based on inter-vehicle distance, vehicle speed maintenance traveling, vehicle collision warning, vehicle lane departure warning, etc.

Further, the microcomputer 12051 can control the driving force generation device, the steering mechanism, the braking device, or the like on the basis of information around the vehicle acquired by the vehicle outside information detection unit 12030 or the vehicle inside information detection unit 12040, thereby performing cooperative control for the purpose of autonomous driving or the like that autonomously travels without depending on an operation of the driver.

In addition, the microcomputer 12051 can output a control command to the body system control unit 12020 on the basis of information outside the vehicle acquired by the vehicle outside information detection unit 12030. For example, the microcomputer 12051 can control a headlamp in accordance with a position of a preceding vehicle or an oncoming vehicle detected by the vehicle outside information detection unit 12030, thereby performing cooperative control for the purpose of anti-glare such as switching a high beam to a low beam.

The voice and image output unit 12052 transmits an output signal of at least one of a voice and an image to output devices capable of visually or audibly notifying information to a passenger or to the outside of the vehicle. In the example of FIG. 26, an audio speaker 12061, a display unit 12062, and an instrument panel 12063 are illustrated as the output devices. The display unit 12062 may include, for example, at least one of an onboard display and a head-up display.

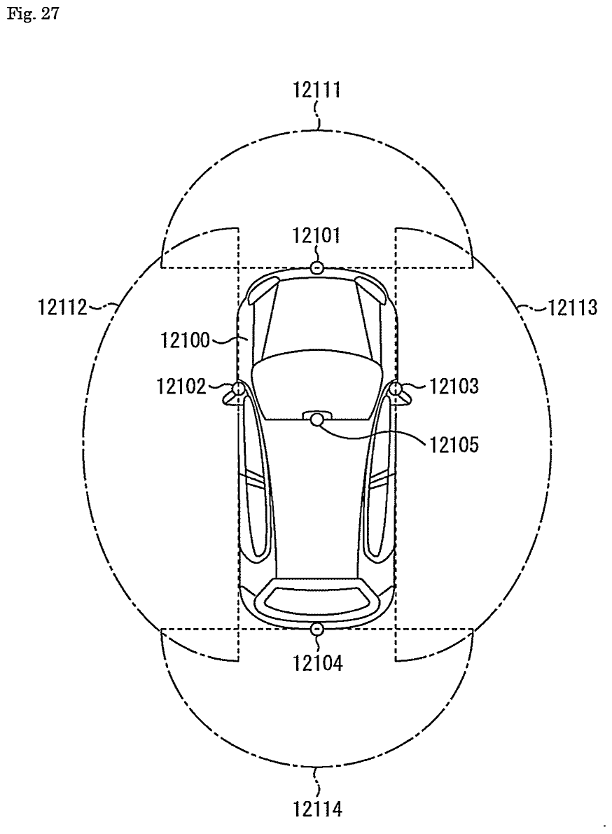

FIG. 27 is a diagram showing an example of installation positions of the imaging unit 12031.

In FIG. 27, the imaging unit 12031 includes imaging units 12101, 12102, 12103, 12104, and 12105.

The imaging units 12101, 12102, 12103, 12104, 12105 are provided at positions of, for example, a front nose, side mirrors, a rear bumper, a back door, and an upper portion of a windshield in a vehicle interior of the vehicle 12100. The imaging unit 12101 provided on the front nose and the imaging unit 12105 provided on the upper portion of the windshield in the vehicle interior mainly acquire images in front of the vehicle 12100. The imaging units 12102 and 12103 provided in the side mirrors mainly acquire images on lateral sides of the vehicle 12100. The imaging unit 12104 provided on the rear bumper or the back door mainly acquires an image behind the vehicle 12100. The imaging unit 12105 provided on the upper portion of the windshield in the vehicle interior is mainly used for detecting a preceding vehicle, a pedestrian, an obstacle, a traffic signal, a traffic sign, a lane, or the like.

Also, FIG. 27 shows an example of imaging ranges of the imaging units 12101 to 12104. An imaging range 12111 indicates an imaging range of the imaging unit 12101 provided on the front nose, Imaging ranges 12112 and 12113 indicate imaging ranges of the imaging units 12102 and 12103 provided on the side mirrors, and an imaging range 12114 indicates an imaging range of the imaging unit 12104 provided on the rear bumper or the back door. For example, by overlaying image data captured by the imaging units 12101 to 12104, a bird's eye view image of the vehicle 12100 viewed from above can be obtained.

At least one of the imaging units 12101 to 12104 may have a function of acquiring distance information. For example, at least one of the imaging units 12101 to 12104 may be a stereo camera including a plurality of image sensors, or may be an image sensor having pixels for phase difference detection.

For example, the microcomputer 12051 can obtain a distance to each three-dimensional object within the imaging ranges 12111 to 12114 and a change of the distance over time (a relative speed with respect to the vehicle 12100) on the basis of distance information obtained from the imaging units 12101 to 12104 and extract the three-dimensional object which is especially the closest three-dimensional object on the road of the vehicle 12100 and is traveling in substantially the same direction as the vehicle 12100 at a predetermined speed (for example, 0 km/h or more) as a preceding vehicle. Further, the microcomputer 12051 can set an inter-vehicle distance to be secured in advance with the rear of the preceding vehicle and perform automatic brake control (including follow-up stop control), automatic acceleration control (including follow-up start control), and the like. In this way, it is possible to perform cooperative control for the purpose of autonomous driving or the like that autonomously travels without depending on the operation of the driver.

For example, the microcomputer 12051 can classify and extract three-dimensional object data regarding three-dimensional objects into a motorcycle, an ordinary vehicle, a large vehicle, a pedestrian, a utility pole, and other three-dimensional objects such as a telephone pole on the basis of the distance information obtained from the imaging units 12101 to 12104 and use it for automatic avoidance of an obstacle. For example, the microcomputer 12051 identifies obstacles around the vehicle 12100 into an obstacle visible to the driver of the vehicle 12100 and an obstacle difficult to see. Then, the microcomputer 12051 can determine a collision risk indicating a degree of a risk of collision with each obstacle, and when the collision risk is above a set value and there is a possibility of collision, output an alarm to the driver via the audio speaker 12061 and the display unit 12062, or perform forced deceleration and avoidance steering via the drive system control unit 12010, thereby performing driving assistance for avoiding the collision.

At least one of the imaging units 12101 to 12104 may be an infrared camera that detects infrared rays. For example, the microcomputer 12051 can recognize a pedestrian by determining whether or not a pedestrian is present in the images captured by the imaging units 12101 to 12104. Such recognition of the pedestrian is performed by, for example, a procedure for extracting feature points in the images captured by the imaging units 12101 to 12104 that are infrared cameras and a procedure for performing pattern matching processing on a series of feature points indicating a contour of an object to determine whether it is a pedestrian or not. When the microcomputer 12051 determines that a pedestrian is present in the images captured by the imaging units 12101 to 12104 and recognizes the pedestrian, the voice and image output unit 12052 controls the display unit 12062 to superimpose and display a rectangular contour line for emphasis on the recognized pedestrian. Further, the voice and image output unit 12052 may control the display unit 12062 to display an icon indicating a pedestrian or the like at a desired position.

Also, the embodiments according to the present technique are not limited to the above-described embodiments, and various modifications can be made without departing from the scope of the present technique.

The present technique may also have a configuration as below.

(1)

An Image Sensor Including:

a substrate;

a first pixel including a first photoelectric conversion region that is provided in the substrate;

a second pixel including a second photoelectric conversion region that is provided in the substrate so as to be adjacent to the first photoelectric conversion region in the substrate;

a first separation portion provided in the substrate so as to be between the first photoelectric conversion region and the second photoelectric conversion region in the substrate; and

a second separation portion that separates a pixel group including at least the first pixel and the second pixel from a pixel group adjacent thereto,

wherein

there is at least one protruding portion of the first separation portion in at least one photoelectric conversion region of the first photoelectric conversion region and the second photoelectric conversion region, and

a p-type impurity region and an n-type impurity region are stacked on a side surface of the protruding portion.

(2)

The image sensor according to the above (1), wherein

the first separation portion includes the protruding portion on each of the first photoelectric conversion region side and the second photoelectric conversion region side.

(3)

The image sensor according to the above (2), wherein

the protruding portion on the first photoelectric conversion region side and the protruding portion on the second photoelectric conversion region side are formed in linear shapes.

(4)

The image sensor according to any one of the above (1) to (3), wherein the first separation portion includes a tungsten layer or an oxide film.

(5)

The image sensor according to any one of the above (1) to (4), wherein the first separation portion is formed of a material that transmits light.

(6)

The image sensor according to any one of the above (1) to (5), wherein

a first material for forming the first separation portion and a second material for forming the second separation portion are different materials.

(7)

The image sensor according to any one of the above (1) to (6), wherein the second separation portion includes a tungsten layer or an oxide film.

(8)

The image sensor according to any one of the above (1) to (7), further including a metal layer on a side opposite to a light incident surface side.

(9)

The image sensor according to any one of the above (1) to (8), further including a plasmon filter on the light incident surface side.

(10)

The image sensor according to any one of the above (1) to (9), wherein the first pixel includes the first photoelectric conversion region and a memory region that holds charges accumulated in the first photoelectric conversion region, and

the first photoelectric conversion region and the memory region are separated by the protruding portion.

(11)

The image sensor according to the above (10), further including:

a transfer unit that transfers the charges accumulated in the first photoelectric conversion region to the memory region; and

a reading unit that reads the charges transferred to the memory region.

(12)

An electronic device including an image sensor, the image sensor including a substrate;

a first pixel including a first photoelectric conversion region that is provided in the substrate;

a second pixel including a second photoelectric conversion region that is provided in the substrate so as to be adjacent to the first photoelectric conversion region; a first separation portion provided in the substrate so as to be between the first photoelectric conversion region and the second photoelectric conversion region; and

a second separation portion that separates a pixel group including at least the first pixel and the second pixel from a pixel group adjacent thereto,

wherein

there is at least one protruding portion of the first separation portion in at least one photoelectric conversion region of the first photoelectric conversion region and the second photoelectric conversion region, and

a p-type impurity region and an n-type impurity region are stacked on a side surface of the protruding portion.

### REFERENCE SIGNS LIST

10 Imaging device
11 Lens group
12 Image sensor
12b Vertical transistor
13 DSP circuit
14 Frame memory
15 Display unit
16 Recording unit
17 Operation system
18 Power supply system
19 Bus line
20 CPU
31 Pixel
41 Pixel array section
42 Vertical drive section
43 Column processing section
44 Horizontal drive section
45 system control section
46 Pixel drive line
47 Vertical signal line
48 Signal processing section
49 Data storage section
70 Si substrate
71 Photodiode
72 Transfer transistor
74 Reset transistor
75 Amplification transistor
76 Selection transistor
80 Transfer transistor
92 Reset transistor
93 Amplification transistor
94 Selection transistor
101 Pixel
102 Si substrate
103 Pixel separation region
104 Pn junction region
105 Pixel group separation region
106 Insulating layer
107 Light shielding film
108 Color filter
110 Insulating film
131 Protruding portion
202 SiO2 film
203 Organic film
301 Light shielding wall
311 Light shielding wall
321 Light shielding wall
322 Light shielding layer
401 Pixel separation region
411 Light shielding wall
421 Light shielding wall
431 Light shielding wall
432 Light shielding layer
501 Plasmon filter
601 Light receiving region
602 Memory region
603 Light shielding layer
611 Write gate
612 Read gate
621 Pn junction region
701 Inter-pixel separation region

1. An image sensor comprising:
a substrate;
a first pixel including a first photoelectric conversion region that is provided in the substrate;
a second pixel including a second photoelectric conversion region that is provided in the substrate so as to be adjacent to the first photoelectric conversion region;
a first separation portion provided in the substrate so as to be between the first photoelectric conversion region and the second photoelectric conversion region; and
a second separation portion that separates a pixel group including at least the first pixel and the second pixel from a pixel group adjacent thereto,
wherein
there is at least one protruding portion of the first separation portion in at least one photoelectric conversion region of the first photoelectric conversion region and the second photoelectric conversion region, and
a p-type impurity region and an n-type impurity region are stacked on a side surface of the protruding portion.

2. The image sensor according to claim 1, wherein
the first separation portion comprises the protruding portion on each of the first photoelectric conversion region side and the second photoelectric conversion region side.

3. The image sensor according to claim 2, wherein
the protruding portion on the first photoelectric conversion region side and the protruding portion on the second photoelectric conversion region side are formed in linear shapes.

4. The image sensor according to claim 1, wherein
the first separation portion comprises a tungsten layer or an oxide film.

5. The image sensor according to claim 1, wherein
the first separation portion is formed of a material that transmits light.

6. The image sensor according to claim 1, wherein
a first material for forming the first separation portion and a second material for forming the second separation portion are different materials.

7. The image sensor according to claim 1, wherein
the second separation portion comprises a tungsten layer or an oxide film.

8. The image sensor according to claim 1, further comprising
a metal layer on a side opposite to a light incident surface side.

9. The image sensor according to claim 1, further comprising
a plasmon filter on the light incident surface side.

10. The image sensor according to claim 1, wherein
the first pixel comprises the first photoelectric conversion region and a memory region that holds charges accumulated in the first photoelectric conversion region, and
the first photoelectric conversion region and the memory region are separated by the protruding portion.

11. The image sensor according to claim 10, further comprising:
a transfer unit that transfers the charges accumulated in the first photoelectric conversion region to the memory region; and
a reading unit that reads the charges transferred to the memory region.

12. An electronic device comprising an image sensor, the image sensor including
a substrate;
a first pixel including a first photoelectric conversion region that is provided in the substrate;
a second pixel including a second photoelectric conversion region that is provided in the substrate so as to be adjacent to the first photoelectric conversion region;
a first separation portion provided in the substrate so as to be between the first photoelectric conversion region and the second photoelectric conversion region; and
a second separation portion that separates a pixel group including at least the first pixel and the second pixel from a pixel group adjacent thereto,
wherein
there is at least one protruding portion of the first separation portion in at least one photoelectric conversion region of the first photoelectric conversion region and the second photoelectric conversion region, and
a p-type impurity region and an n-type impurity region are stacked on a side surface of the protruding portion.
